(19) United States
(12) Patent Application Publication
(10) Pub. No.: US 2026/0237352 A1
(43) Pub. Date: Aug. 13, 2026

(54) Shift Register, Driving Method Thereof, Display Substrate and Display Device

(71) Applicants: Chongqing BOE Display Technology Co.,Ltd., Chongqing (CN); BOE Technology Group Co., Ltd., Beijing (CN)

(72) Inventors: Teng CHEN, Beijing (CN); Dawei SHI, Beijing (CN); Wentao WANG, Beijing (CN); Faming JIANG, Beijing (CN); Shuaizhuo LIU, Beijing (CN); Chuanyong LI, Beijing (CN)

(21) Appl. No.: 18/029,900

(22) PCT Filed: Jun. 7, 2022
(86) PCT No.: PCT/CN2022/097393

§ 371 Date: May 22, 2025

(51) Int. Cl. G09G 3/3266; G11C 19/28

(52) U.S. Cl. CPC G09G 3/3266; G11C 19/28; G09G 2300/0426; G09G 2300/0842; G09G 2310/0286; G09G 2330/021

(57) ABSTRACT

The present disclosure provides a shift register, a driving method thereof, a display substrate and a display device. The shift register includes a storage sub-circuit, a node control sub-circuit and an output control sub-circuit, wherein the storage sub-circuit, electrically connected to a first node and a first power supply terminal respectively, is configured to store a voltage difference between a signal of the first node and a signal of the first power supply terminal; the node control sub-circuit, electrically connected to a signal input terminal, a first clock signal terminal, a second clock signal terminal, the first node and a second node respectively, is configured to provide a signal of the signal input terminal to the first node under the control of the first clock signal terminal and provide the signal of the first node to the second node under the control of the second clock signal terminal.

### CROSS-REFERENCE TO RELATED APPLICATION

The present application is a U.S. National Phase Entry of International Application No. PCT/CN2022/097393 having an international filing date of Jun. 7, 2022. The above-identified application is hereby incorporated by reference.

### TECHNICAL FIELD

The present disclosure relates to, but is not limited to, the field of display technology, and more particularly, to a shift register, a driving method thereof, a display substrate and a display device.

### BACKGROUND

Organic light emitting diodes (OLEDs) and quantum-dot light emitting diodes (QLEDs), which are active light emitting display elements, have advantages such as self-luminescence, wide viewing angle, high contrast, low power consumption, extremely high response speed, lightness and thinness, bendability, low cost, etc. With the continuous development of display technology, flexible display devices (Flexible Display) that use OLEDs or QLEDs as light emitting elements and use thin film transistors (TFTs) for signal control have become mainstream products in the field of display at present.

### SUMMARY

The following is a summary of subject matters described in the present disclosure in detail. The summary is not intended to limit the protection scope of the claims.

In a first aspect, the present disclosure provides a shift register including a storage sub-circuit, a node control sub-circuit and an output control sub-circuit, wherein
the storage sub-circuit, electrically connected to a first node and a first power supply terminal respectively, is configured to store a voltage difference between a signal of the first node and a signal of the first power supply terminal;
the node control sub-circuit, electrically connected to a signal input terminal, a first clock signal terminal, a second clock signal terminal, the first node and a second node respectively, is configured to provide a signal of the signal input terminal to the first node under the control of the first clock signal terminal and provide the signal of the first node to the second node under the control of the second clock signal terminal; and
the output control sub-circuit, electrically connected to the second node, the first power supply terminal, a second power supply terminal and a signal output terminal respectively, is configured to provide the signal of the first power supply terminal or a signal of the second power supply terminal to the signal output terminal under the control of the second node.

In some possible implementations, the output control sub-circuit includes a first output control sub-circuit and a second output control sub-circuit,
the first output control sub-circuit, electrically connected to the second node, a third node, the first power supply terminal and the second power supply terminal respectively, is configured to provide the signal of the first power supply terminal or the signal of the second power supply terminal to the third node under the control of the second node; and
the second output control sub-circuit, electrically connected to the third node, the first power supply terminal, the second power supply terminal and the signal output terminal respectively, is configured to provide the signal of the first power supply terminal or the signal of the second power supply terminal to the signal output terminal under the control of the third node.

In some possible implementations, the shift register further includes a noise reduction sub-circuit,
the noise reduction sub-circuit, electrically connected to the first clock signal terminal, the second clock signal terminal, the first power supply terminal, the second power supply terminal, the second node and the third node respectively, is configured to provide the signal of the first power supply terminal or the signal of the second power supply terminal to the second node under the control of the first clock signal terminal, the second clock signal terminal and the third node.

In some possible implementations, the storage sub-circuit includes a capacitor including a first plate and a second plate,
the first plate of the capacitor is electrically connected to the first node, and the second plate of the capacitor is electrically connected to the first power supply terminal.

In some possible implementations, the node control sub-circuit includes a first transistor and a second transistor,
a control electrode of the first transistor is electrically connected to the first clock signal terminal, a first electrode of the first transistor is electrically connected to the signal input terminal, and a second electrode of the first transistor is electrically connected to the first node; and
a control electrode of the second transistor is electrically connected to the second clock signal terminal, a first electrode of the second transistor is electrically connected to the first node, and a second electrode of the second transistor is electrically connected to the second node.

In some possible implementations, the first output control sub-circuit includes a third transistor and a fourth transistor, and the second output control sub-circuit includes a fifth transistor and a sixth transistor,
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal; and
the third transistor and the fourth transistor are of opposite types, and the fifth transistor and the sixth transistor are of opposite types.

In some possible implementations, the noise reduction sub-circuit includes a seventh transistor, an eighth transistor, a ninth transistor and a tenth transistor,
a control electrode of the seventh transistor is electrically connected to the first clock signal terminal, a first electrode of the seventh transistor is electrically connected to the first power supply terminal, and a second electrode of the seventh transistor is electrically connected to a first electrode of the eighth transistor;
a control electrode of the eighth transistor is electrically connected to the third node, and a second electrode of the eighth transistor is electrically connected to the second node;
a control electrode of the ninth transistor is electrically connected to the third node, a first electrode of the ninth transistor is electrically connected to the second node, and a second electrode of the ninth transistor is electrically connected to a second electrode of the tenth transistor;
a control electrode of the tenth transistor is electrically connected to the second clock signal terminal, and a first electrode of the tenth transistor is electrically connected to the second power supply terminal; and
the seventh transistor and the eighth transistor are of the same type, the ninth transistor and the tenth transistor are of the same type, and the seventh transistor and the ninth transistor are of opposite types.

In some possible implementations, the storage sub-circuit includes a capacitor including a first plate and a second plate; the node control sub-circuit includes a first transistor and a second transistor; and the output control sub-circuit includes a third transistor, a fourth transistor, a fifth transistor and a sixth transistor, wherein
the first plate of the capacitor is electrically connected to the first node, and the second plate of the capacitor is electrically connected to the first power supply terminal;
the control electrode of the first transistor is electrically connected to the first clock signal terminal, a first electrode of the first transistor is electrically connected to the signal input terminal, and a second electrode of the first transistor is electrically connected to the first node;
a control electrode of the second transistor is electrically connected to the second clock signal terminal, a first electrode of the second transistor is electrically connected to the first node, and a second electrode of the second transistor is electrically connected to the second node;
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal; and
the first transistor, the second transistor, the third transistor and the fifth transistor are P-type transistors, and the fourth transistor and the sixth transistor are N-type transistors and are oxide transistors.

In some possible implementations, the shift register further includes a noise reduction sub-circuit; the storage sub-circuit includes a capacitor including a first plate and a second plate; the node control sub-circuit includes a first transistor and a second transistor; the output control sub-circuit includes a third transistor, a fourth transistor, a fifth transistor and a sixth transistor; the noise reduction sub-circuit includes a seventh transistor, an eighth transistor, a ninth transistor and a tenth transistor,
the first plate of the capacitor is electrically connected to the first node, and the second plate of the capacitor is electrically connected to the first power supply terminal;
a control electrode of the first transistor is electrically connected to the first clock signal terminal, a first electrode of the first transistor is electrically connected to the signal input terminal, and a second electrode of the first transistor is electrically connected to the first node;
a control electrode of the second transistor is electrically connected to the second clock signal terminal, a first electrode of the second transistor is electrically connected to the first node, and a second electrode of the second transistor is electrically connected to the second node;
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal;
a control electrode of the seventh transistor is electrically connected to the first clock signal terminal, a first electrode of the seventh transistor is electrically connected to the first power supply terminal, and a second electrode of the seventh transistor is electrically connected to a first electrode of the eighth transistor;
a control electrode of the eighth transistor is electrically connected to the third node, and a second electrode of the eighth transistor is electrically connected to the second node;
a control electrode of the ninth transistor is electrically connected to the third node, a first electrode of the ninth transistor is electrically connected to the second node, and a second electrode of the ninth transistor is electrically connected to a second electrode of the tenth transistor;
a control electrode of the tenth transistor is electrically connected to the second clock signal terminal, and a first electrode of the tenth transistor is electrically connected to the second power supply terminal; and
the first transistor, the second transistor, the third transistor, the fifth transistor, the seventh transistor and the eighth transistor are P-type transistors, and the fourth transistor, the sixth transistor, the ninth transistor and the tenth transistor are N-type transistors and are oxide transistors.

In some possible implementations, a clock signal of the first clock signal terminal and a clock signal of the second clock signal terminal are signals which are inverted with respect to each other;
the signal of the signal input terminal is a first pulse signal, a duration of which is equal to a period of the clock signal of the first clock signal terminal; and
a signal of the signal output terminal is a second pulse signal, a duration of which is equal to the duration of the first pulse signal, start time of the second pulse signal being end time of the first pulse signal.

In some possible implementations, the clock signal of the first clock signal terminal and the clock signal of the second clock signal terminal are signals which are inverted with respect to each other;
the signal of the signal input terminal is a third pulse signal, a duration of which is equal to N times the period of the clock signal of the first clock signal terminal, N being a positive integer greater than or equal to 2; and
the signal of the signal output terminal is a fourth pulse signal, a duration of which is equal to the duration of the third pulse signal, a difference between start time of the fourth pulse signal and start time of the third pulse signal being equal to the period of the clock signal of the first clock signal terminal.

In a second aspect, the present invention further provides a display substrate including a display area and a non-display area, the display substrate including a substrate and a circuit structure layer disposed on the substrate, the circuit structure layer including a gate driving circuit located in the non-display area and a pixel circuit, which is arranged in an array, located in the display area, the gate driving circuit including a plurality of cascaded shift registers described above, and the pixel circuit including a light emitting signal line, a scan signal line and a reset signal line,
a signal output terminal of an i-th stage shift register is electrically connected to a signal input terminal of an (i+1)-th stage shift register, 1≤i≤M−1, and M being the total number of stages of the shift registers; and
the gate driving circuit is electrically connected to at least one of the light emitting signal line, the scan signal line and the reset signal line.

In some possible implementations, the display substrate further includes a first clock signal line, a second clock signal line, a first power supply line and a second power supply line extending along a first direction, the first power supply line, the second power supply line, the first clock signal line and the second clock signal line being arranged along a second direction, and the first direction intersecting the second direction;
first power supply terminals of all the shift registers are electrically connected to the first power supply line, second power supply terminals of all the shift registers are electrically connected to the second power supply line, a first clock signal terminal of the i-th stage shift register is electrically connected to the first clock signal line, a second clock signal terminal of the i-th stage shift register is electrically connected to the second clock signal line, a first clock signal terminal of the (i+1)-th stage shift register is electrically connected to the second clock signal line, and a second clock signal terminal of the (i+1)-th stage shift register is electrically connected to the first clock signal line.

In some possible implementations, each of the shift registers includes a first transistor through a tenth transistor and a capacitor, the capacitor including a first plate and second plate, and the circuit structure layer including a first semiconductor layer, a first insulating layer, a first conductive layer, a second insulating layer, a second conductive layer, a third insulating layer, a second semiconductor layer, a fourth insulating layer, a third conductive layer, a fifth insulating layer and a fourth conductive layer which are sequentially stacked on the substrate,
the first semiconductor layer includes an active layer of the first transistor, an active layer of the second transistor, an active layer of the third transistor, an active layer of the fifth transistor, an active layer of the seventh transistor and an active layer of the eighth transistor;
the first conductive layer includes a control electrode of the first transistor, a control electrode of the second transistor, a control electrode of the third transistor, a control electrode of the fifth transistor, a control electrode of the seventh transistor, a control electrode of the eighth transistor, the first plate of the capacitor and a signal output line;
the second conductive layer includes the second plate of the capacitor;
the second semiconductor layer includes an active layer of the fourth transistor, an active layer of the sixth transistor, an active layer of the ninth transistor and an active layer of the tenth transistor;
the third conductive layer includes a control electrode of the fourth transistor, a control electrode of the sixth transistor, a control electrode of the ninth transistor and a control electrode of the tenth transistor;
the fourth conductive layer includes the first clock signal line, the second clock signal line, the first power supply line, the second power supply line, first electrodes and second electrodes of the first transistor through the sixth transistor, a first electrode of the seventh transistor, a second electrode of the eighth transistor, a first electrode of the ninth transistor, a first electrode of the tenth transistor, a first connection signal line, a second connection signal line and a third connection signal line;
the signal output line is connected to the second electrode of the fifth transistor and the second electrode of the sixth transistor respectively;
the first connection signal line is connected to the active layer of the third transistor and the control electrode of the ninth transistor respectively;
the second connection signal line is connected to the active layer of the third transistor and the control electrode of the eighth transistor respectively; and
the third connection signal line is connected to the control electrode of the tenth transistor and the control electrode of the second transistor respectively.

In some possible implementations, the fifth transistor and the sixth transistor are located at the same side of the first power supply line, and the fifth transistor and the sixth transistor are arranged along the first direction;
the third transistor is located at one side of the fifth transistor away from the first power supply line, the fourth transistor is located at one side of the sixth transistor away from the first power supply line, the third transistor and the fourth transistor are arranged along the first direction, the third transistor and the fifth transistor are arranged along the second direction, and the fourth transistor and the sixth transistor are arranged along the second direction;
the eighth transistor is located at one side of the third transistor away from the fifth transistor, the ninth transistor is located at one side of the fourth transistor away from the sixth transistor, the eighth transistor and the ninth transistor are arranged along the first direction, the third transistor and the eighth transistor are arranged along the second direction, and the fourth transistor and the ninth transistor are arranged along the second direction;
the seventh transistor is located at one side of the eighth transistor away from the third transistor, the tenth transistor is located at one side of the ninth transistor away from the fourth transistor, the seventh transistor and the tenth transistor are arranged along the first direction, the seventh transistor and the eighth transistor are arranged along the second direction, and the ninth transistor and the tenth transistor are arranged along the second direction;
the second transistor is located between the seventh transistor and the tenth transistor, the first transistor is located at one side of the seventh transistor away from the eighth transistor, and the capacitor is located at one side of the tenth transistor away from the ninth transistor; and
the second power supply line is located at one side of the capacitor away from the tenth transistor, the first clock signal line is located at one side of the second power supply line away from the capacitor, and the second clock signal line is located at one side of the first power supply line away from the second power supply line.

In some possible implementations, the active layer of the first transistor and the active layer of the second transistor form an integrated structure, and the active layer of the seventh transistor and the active layer of the eighth transistor form an integrated structure;
the active layer of the third transistor includes a first active connection part, a second active connection part and a third active connection part, the first active connection part and the third active connection part extend along the first direction, and the second active connection part extends along the second direction and is connected to the first active connection part and the third active connection part respectively;
the first active connection part is located at one side of the second active connection part close to the integrated structure of the active layer of the seventh transistor and the active layer of the eighth transistor, and the third active connection part is located at one side of the second active connection part away from the integrated structure of the active layer of the seventh transistor and the active layer of the eighth transistor;
a straight line extending along the second direction passes through the first active connection part and the active layer of the second transistor; and
a straight line extending along the second direction passes through the third active connection part and the active layer of the first transistor.

In some possible implementations, the first plate of the capacitor includes a first capacitor body part and a first capacitor connection part connected to each other;
the control electrode of the first transistor and the control electrode of the seventh transistor form an integrated structure, and are located at one side of the first capacitor connection part away from the first capacitor body part;
a virtual straight line extending along the second direction passes through the control electrode of the eighth transistor and the integrated structure of the control electrode of the first transistor and the control electrode of the seventh transistor;
a virtual straight line extending along the second direction passes through the control electrode of the third transistor and the control electrode of the eighth transistor;
a virtual straight line extending along the second direction passes through the control electrode of the fifth transistor and the control electrode of the third transistor; and
a virtual straight line extending along the second direction passes through the signal output line and the control electrode of the second transistor.

In some possible implementations, the second plate of the capacitor includes a second capacitor body part and a second capacitor connection part connected to each other, wherein the second capacitor connection part is located at one side of the second capacitor body part;
the area of the first capacitor body part of the first plate of the capacitor is greater than the area of the second capacitor body part of the second plate of the capacitor; and
orthographic projections of the second capacitor body part and the second capacitor connection part on the substrate overlap at least partially with an orthographic projection of the first capacitor body part of the first plate of the capacitor on the substrate, and do not overlap with an orthographic projection of the first capacitor connection part of the first plate of the capacitor on the substrate.

In some possible implementations, an orthographic projection of the active layer of the sixth transistor on the substrate and an orthographic projection of the active layer of the fifth transistor on the substrate are located at two opposite sides of an orthographic projection of the signal output line on the substrate respectively, and a straight line extending along the first direction passes through the active layer of the fifth transistor and the active layer of the sixth transistor;
a straight line extending along the first direction passes through the active layer of the fourth transistor and the third active connection part of the active layer of the third transistor; and
a straight line extending along the first direction passes through the active layer of the ninth transistor and the active layer of the eighth transistor, and a straight line extending along the first direction passes through the active layer of the tenth transistor and the active layer of the seventh transistor.

In some possible implementations, a virtual straight line extending along the second direction passes through the control electrode of the fourth transistor, the control electrode of the sixth transistor and the control electrode of the ninth transistor;
the control electrode of the tenth transistor includes a first electrode connection part, a second electrode connection part and a third electrode connection part, wherein the first electrode connection part and the third electrode connection part extend along the second direction, and the second electrode connection part extends along the first direction and is connected to the first electrode connection part and the third electrode connection part respectively;
the first electrode connection part is located at one side of the second electrode connection part close to the control electrode of the ninth transistor, and the third electrode connection part is located at one side of the second electrode connection part away from the control electrode of the ninth transistor;
a virtual straight line extending along the second direction passes through an orthographic projection of the first electrode connection part of the control electrode of the tenth transistor on the substrate and the orthographic projection of the first capacitor body part of the first plate of the capacitor on the substrate; and
an orthographic projection of the third electrode connection part of the control electrode of the tenth transistor on the substrate is located at one side of an orthographic projection of the first plate of the capacitor on the substrate away from an orthographic projection of the integrated structure of the control electrode of the first transistor and the control electrode of the seventh transistor on the substrate.

In some possible implementations, a pattern of a plurality of via holes is provided in the fifth insulating layer, wherein the pattern of the plurality of via holes includes first through sixth via hole provided in the first insulating layer, the second insulating layer and the fifth insulating layer, seventh through thirteenth via hole provided in the second through fifth insulating layer, a fourteenth via hole provided in the third through fifth insulating layer, fifteenth through eighteenth via hole provided in the fourth and fifth insulating layer, and nineteenth through twenty-second via hole provided in the fifth insulating layer;
the third via holes expose the active layer of the third transistor, and the twenty-second via holes expose the control electrode of the tenth transistor;
the number of the third via holes is four, a virtual straight line extending along the first direction passes through the first one of the third via holes and the second one of the third via holes, and the first one of the third via holes and the second one of the third via holes expose the first active connection part of the active layer of the third transistor, a virtual straight line extending along the first direction passes through the third one of the third via holes and the fourth one of the third via holes, the third one of the third via holes and the fourth one of the third via hole expose the third active connection part of the active layer of the third transistor, and a virtual straight line extending along the second direction passes through the second one of the third via holes and the third one of the third via holes; and
the number of the twenty-second via holes is two, the first one of the twenty-second via holes exposes the second electrode connection part of the control electrode of the tenth transistor, and the second one of the twenty-second via holes exposes the third electrode connection part of the control electrode of the tenth transistor.

In some possible implementations, the first electrode of the third transistor, the first electrode of the fifth transistor, the first electrode of the seventh transistor and the first power supply line form an integrated structure, the first electrode of the fourth transistor, the first electrode of the sixth transistor, the first electrode of the tenth transistor and the second power supply line form an integrated structure, the second electrode of the first transistor and the first electrode of the second transistor form an integrated structure, the second electrode of the third transistor and the second electrode of the fourth transistor form an integrated structure, the second electrode of the second transistor, the second electrode of the eighth transistor and the first electrode of the ninth transistor form an integrated structure, and the second electrode of the fifth transistor and the second electrode of the sixth transistor form an integrated structure;
an orthographic projection of the first power supply line on the substrate overlaps at least partially with the orthographic projection of the signal output line on the substrate.
an orthographic projection of the second power supply line on the substrate overlaps partially with orthographic projections of the integrated structure of the control electrode of the first transistor and the control electrode of the seventh transistor, the control electrode of the tenth transistor and the second capacitor connection part of the second plate of the capacitor on the substrate;
an orthographic projection of the first clock signal line on the substrate overlaps partially with orthographic projections of the control electrode of the tenth transistor and the integrated structure of the control electrode of the first transistor and the control electrode of the seventh transistor on the substrate;
an orthographic projection of the second clock signal line overlaps partially with an orthographic projection of the control electrode of the transistor, to which the second clock signal line is connected, on the substrate;
an orthographic projection of the integrated structure of the second electrode of the first transistor and the first electrode of the second transistor on the substrate overlaps partially with the orthographic projection of the first capacitor connection part of the first plate of the capacitor on the substrate;
an orthographic projection of the integrated structure of the second electrode of the third transistor and the second electrode of the fourth transistor on the substrate overlaps partially with orthographic projections of the control electrode of the sixth transistor and the control electrode of the fifth transistor on the substrate;
an orthographic projection of the integrated structure of the second electrode of the fifth transistor and the second electrode of the sixth transistor on the substrate overlaps partially with the orthographic projection of the signal output line on the substrate;
an orthographic projection of the integrated structure of the second electrode of the second transistor, the second electrode of the eighth transistor and the first electrode of the ninth transistor on the substrate overlaps partially with orthographic projections of the control electrode of the third transistor and the control electrode of the fourth transistor on the substrate;
an orthographic projection of the first connection signal line on the substrate overlaps partially with an orthographic projection of the control electrode of the ninth transistor on the substrate;
an orthographic projection of the second connection signal line on the substrate overlaps partially with an orthographic projection of the control electrode of the eighth transistor on the substrate; and
an orthographic projection of the third connection signal line on the substrate overlaps partially with orthographic projections of the control electrode of the second transistor and the control electrode of the tenth transistor on the substrate.

In some possible implementations, the first electrode and the second electrode of the third transistor are connected to the active layer of the third transistor through the third one of the third via holes and the fourth one of the third via holes respectively;
the first connection signal line is connected to the active layer of the third transistor through the first one of the third via holes;
the second connection signal line is connected to the active layer of the third transistor through the second one of the third via holes;
the third connection signal line is connected to the control electrode of the tenth transistor through the first one of the twenty-second via holes; and
one of the first clock signal line and the second clock signal line is connected to the control electrode of the tenth transistor through the second one of the twenty-second via holes.

In a third aspect, the present disclosure further provides a display device including the display substrate described above.

In the fourth aspect, the present disclosure further provides a driving method for a shift register, which is used for driving the shift register described above. The method includes:
a storage sub-circuit storing a voltage difference between a signal of a first node and a signal of a first power supply terminal;
a node control sub-circuit providing a signal of a signal input terminal to the first node under the control of a first clock signal terminal, and providing the signal of the first node to a second node under the control of a second clock signal terminal; and
an output control sub-circuit providing the signal of the first power supply terminal or a signal of a second power supply terminal to a signal output terminal under the control of the second node.

Other aspects may become clear after the accompanying drawings and the detailed description are read and understood.

### BRIEF DESCRIPTION OF DRAWINGS

The accompanying drawings are intended to provide an understanding for technical schemes of the present disclosure and form a part of the specification, and are used to explain the technical schemes of the present disclosure together with embodiments of the present disclosure, and not intended to form limitations to the technical schemes of the present disclosure.

FIG. 1 is a schematic structural diagram of a shift register in accordance with an embodiment of the present disclosure;

FIG. 2 is a schematic structural diagram of an output control sub-circuit in accordance with an exemplary embodiment;

FIG. 3 is a schematic structural diagram of a shift register in accordance with an exemplary embodiment;

FIG. 4 is an equivalent circuit diagram of a storage sub-circuit in accordance with an exemplary embodiment;

FIG. 5 is an equivalent circuit diagram of a node control sub-circuit in accordance with an exemplary embodiment;

FIG. 6 is an equivalent circuit diagram of an output control sub-circuit in accordance with an exemplary embodiment;

FIG. 7 is an equivalent circuit diagram of a noise reduction sub-circuit in accordance with an exemplary embodiment;

FIG. 8 is an equivalent circuit diagram of a shift register in accordance with an exemplary embodiment;

FIG. 9 is an equivalent circuit diagram of a shift register in accordance with another exemplary embodiment;

FIG. 10 is a working sequence diagram of a shift register in accordance with an exemplary embodiment;

FIG. 11 is a working sequence diagram of a shift register in accordance with another exemplary embodiment;

FIG. 12 is a schematic structural diagram of a display substrate in accordance with an exemplary embodiment;

FIG. 13 is a schematic diagram after a pattern of a first semiconductor layer is formed;

FIG. 14A is a schematic diagram of a pattern of a first conductive layer;

FIG. 14B is a schematic diagram after a pattern of first conductive layer is formed;

FIG. 15A is a schematic diagram of a pattern of a second conductive layer;

FIG. 15B is a schematic diagram after a pattern of a second conductive layer is formed;

FIG. 16A is a schematic diagram of a pattern of a second semiconductor layer;

FIG. 16B is a schematic diagram after a pattern of a second semiconductor layer is formed;

FIG. 17A is a schematic diagram of a pattern of a third conductive layer;

FIG. 17B is a schematic diagram after a pattern of a third conductive layer is formed;

FIG. 18 is a schematic diagram after a pattern of a fifth insulating layer is formed;

FIG. 19A is a schematic diagram of a pattern of a fourth conductive layer; and

FIG. 19B is a schematic diagram after a pattern of a fourth conductive layer is formed.

### DETAILED DESCRIPTION

In order to make objects, technical schemes and advantages of the present disclosure more clear, examples of the present disclosure will be described below in detail in combination with the drawings. It should be noted that embodiments may be implemented in a number of different forms. Those of ordinary skills in the art may readily understand the fact that implementations and contents may be transformed into various forms without departing from the purpose and scope of the present disclosure. Therefore, the present disclosure should not be interpreted as being limited to the contents recorded in following embodiments only. The embodiments in the present disclosure and features in the embodiments can be arbitrarily combined with each other if there are no conflicts. In order to keep the following description of the embodiments of the present disclosure clear and concise, detailed descriptions of a portion of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure can be used as references in the actual processes, but are not limited thereto. For example, the width-to-length ratio of a channel, the thickness of each film layer and the spacing between two film layers, and the width of each signal line and the spacing between two signal lines can be adjusted according to actual needs. The quantity of pixels in a display substrate and the quantity of sub-pixels in each pixel are not limited to the number shown in the drawings. The drawings described in the present disclosure are a schematic structure diagram only, and one implementation of the present disclosure is not limited to the shapes or numerical values shown in the drawings.

Ordinal numerals such as “first”, “second”, “third” and the like in the specification are set in order to avoid confusion of the constituent elements, but not to set a limit in quantity.

For convenience, the terms such as “middle”, “upper”, “lower”, “front”, “back”, “vertical”, “horizontal”, “top”, “bottom”, “inside”, “outside” and the like indicating orientation or position relationships are used in the specification to illustrate position relationships between the constituent elements with reference to the drawings, and are intended to facilitate description of the specification and simplification of the description, but not to indicate or imply that the mentioned device or element must have a specific orientation or be constructed and operated in a specific orientation, therefore, they should not be understood as limitations to the present disclosure. The position relationships between the constituent elements are appropriately changed according to directions of the constituent elements described. Therefore, words and phrases used in the specification are not limited and appropriate substitutions may be made according to situations.

Unless otherwise specified and defined explicitly, the terms “installed”, “coupled” and “connected” should be understood in a broad sense in the specification. For example, the connection may be a fixed connection, a detachable connection or an integrated connection, or may be a mechanical connection or an electrical connection, or may be a direct connection, an indirect connection through intermediate components, or communication inside two components. The specific meanings of the above terms in the present disclosure can be understood by a person of ordinary skill in the art according to the specific situations.

In the specification, a transistor refers to a component which at least includes three terminals, a gate electrode, a drain electrode and a source electrode. The transistor has a channel region between the drain electrode (drain electrode terminal, drain region or drain) and the source electrode (source electrode terminal, source region or source), and a current can flow through the drain electrode, the channel region and the source electrode. It should be noted that in the specification, the channel region refers to a region which the current mainly flows through.

In the specification, the first electrode may be a drain electrode and the second electrode may be a source electrode, or the first electrode may be a source electrode and the second electrode may be a drain electrode. In the case that transistors with opposite polarities are used or the case that a current direction is changed during circuit operation, functions of the “source electrode” and the “drain electrode” are sometimes interchangeable. Therefore, the “source electrode” and the “drain electrode” can be interchanged in the specification.

In the specification, “electrical connection” includes a case where the constituent elements are connected together through an element with a certain electrical effect. The “element with the certain electrical effect” is not particularly limited as long as electrical signals can be sent and received between the connected constituent elements. Examples of the “element with the certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is greater than −10° and less than 10°, and thus also includes a state in which the angle is greater than −5° and less than 5°. In addition, “vertical” refers to a state in which an angle formed by two straight lines is greater than 80° and less than 100°, and thus also includes a state in which the angle is greater than 85° and less than 95°.

In the specification, “film” and “layer” may be interchangeable. For example, sometimes “conductive layer” may be replaced by “conductive film”. Similarly, sometimes “insulating film” may be replaced by “insulating layer”.

“Being disposed on the same layer” mentioned in the specification means that two (or more than two) structures are formed by patterning through the same running of patterning processes, and they may be made of the same or different materials. For example, materials of the precursors forming a plurality of structures disposed on the same layer are the same, and the resulting materials may be the same or different.

Triangle, rectangle, trapezoid, pentagon and hexagon in the specification are not in the strict sense, and they may be approximate triangle, rectangle, trapezoid, pentagon or hexagon, in which there may be some small deformation caused by tolerance, or there may be chamfers, arc edges and deformation, etc.

“About” in the present disclosure means that a boundary is defined loosely and numerical values in process and measurement error ranges are allowed.

A display substrate includes a pixel circuit, a light emitting element and a gate driving circuit, wherein the gate driving circuit is configured to provide a gate signal to the pixel circuit so that the pixel circuit can drive the light emitting element to emit light. The area occupied by the gate driving circuit and the power consumption of the gate driving circuit are relatively large.

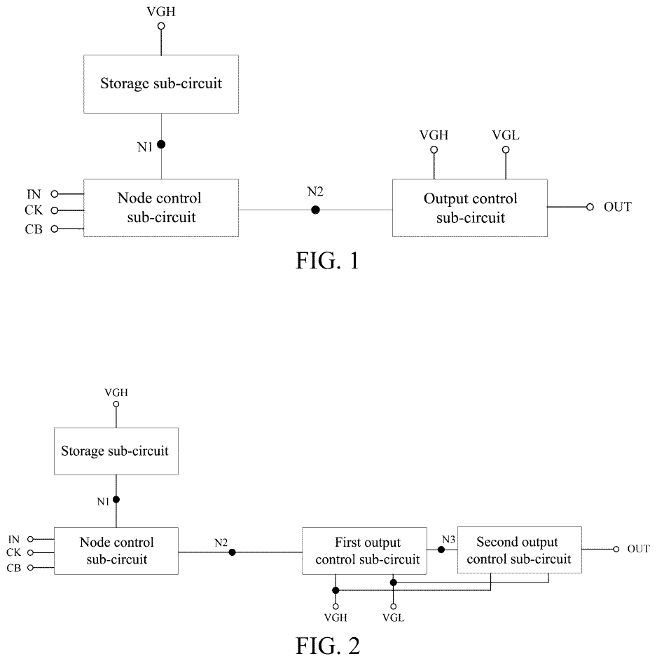

FIG. 1 is a schematic structural diagram of a shift register in accordance with an embodiment of the present disclosure. As shown in FIG. 1, the shift register in accordance with the embodiment of the present disclosure may include a storage sub-circuit, a node control sub-circuit and an output control sub-circuit.

As shown in FIG. 1, the storage sub-circuit, electrically connected to a first node N1 and a first power supply terminal VGH respectively, is configured to store a voltage difference between a signal of the first node N1 and a signal of the first power supply terminal VGH; the node control sub-circuit, electrically connected to a signal input terminal IN, a first clock signal terminal CK, a second clock signal terminal CB, the first node N1 and a second node N2 respectively, is configured to provide a signal of the signal input terminal IN to the first node N1 under the control of the first clock signal terminal CK and provide the signal of the first node N1 to the second node N2 under the control of the second clock signal terminal CB; and the output control sub-circuit, electrically connected to the second node N2, the first power supply terminal VGH, a second power supply terminal VGL and a signal output terminal OUT respectively, is configured to provide the signal of the first power supply terminal VGH or a signal of the second power supply terminal VGL to the signal output terminal OUT under the control of the second node N2.

In an exemplary embodiment, the first power supply terminal VGH continuously provides high-level signals, and the second power supply terminal VGL continuously provides low-level signals.

In an exemplary embodiment, signals of the first clock signal terminal CK and the second clock signal terminal CB may be periodic pulse signals.

The shift register in accordance with the embodiment of the present disclosure includes a storage sub-circuit, a node control sub-circuit and an output control sub-circuit, wherein the storage sub-circuit, electrically connected to a first node and a first power supply terminal respectively, is configured to store a voltage difference between a signal of the first node and a signal of the first power supply terminal; the node control sub-circuit, electrically connected to a signal input terminal, a first clock signal terminal, a second clock signal terminal, the first node and a second node respectively, is configured to provide a signal of the signal input terminal to the first node under the control of the first clock signal terminal and provide the signal of the first node to the second node under the control of the second clock signal terminal; and the output control sub-circuit, electrically connected to the second node, the first power supply terminal, a second power supply terminal and a signal output terminal respectively, is configured to provide the signal of the first power supply terminal or a signal of the second power supply terminal to the signal output terminal under the control of the second node. The shift register in accordance with the present disclosure can reduce the area occupied by the shift register and power consumption through coordination of the storage sub-circuit, the node control sub-circuit and the output control sub-circuit.

FIG. 2 is a schematic structural diagram of an output control sub-circuit in accordance with an exemplary embodiment. As shown in FIG. 2, in an exemplary embodiment, the output control sub-circuit may include a first output control sub-circuit and a second output control sub-circuit.

As shown in FIG. 2, the first output control sub-circuit, electrically connected to the second node N2, a third node N3, the first power supply terminal VGH and the second power supply terminal VGL respectively, is configured to provide the signal of the first power supply terminal VGH or the second power supply terminal VGL to the third node N3 under the control of the second node N2; the second output control sub-circuit, electrically connected to the third node N3, the first power supply terminal VGH, the second power supply terminal VGL and the signal output terminal OUT respectively, is configured to provide the signal of the first power supply terminal VGH or the second power supply terminal VGL to the signal output terminal OUT under the control of the third node N3.

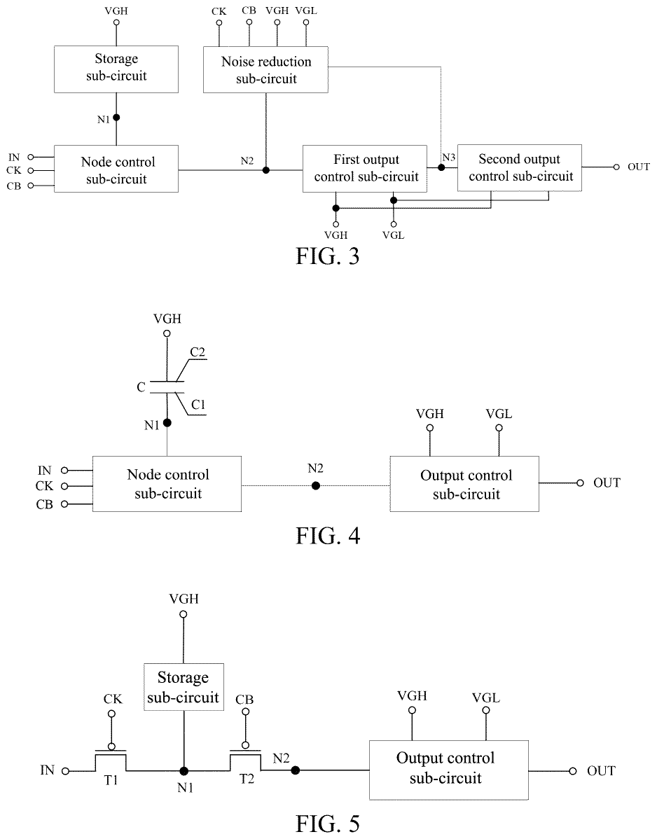

FIG. 3 is a schematic structural diagram of a shift register in accordance with an exemplary embodiment. As shown in FIG. 3, in an exemplary embodiment, the shift register may further include a noise reduction sub-circuit, wherein the noise reduction sub-circuit, electrically connected to the first clock signal terminal CK, the second clock signal terminal CB, the first power supply terminal VGH, the second power supply terminal VGL, the second node N2 and the third node N3 respectively, is configured to provide the signal of the first power supply terminal VGH or the second power supply terminal VGL to the second node N2 under the control of the first clock signal terminal CK, the second clock signal terminal CB and the third node N3.

In the present disclosure, the noise reduction sub-circuit can be configured to maintain a voltage value of a signal of the second node N2, so that the signal of the second node N2 is in a stable state, to prevent change in the voltage value of the signal due to floating of the second node N2, thereby improving the reliability of the shift register.

FIG. 4 is an equivalent circuit diagram of a storage sub-circuit in accordance with an exemplary embodiment. As shown in FIG. 4, in an exemplary embodiment, the storage sub-circuit may include a capacitor C including a first plate C1 and a second plate C2. The first plate C1 of the capacitor C is electrically connected to the first node N1, and the second plate C2 of the capacitor C is electrically connected to the first power supply terminal VGH.

An exemplary structure of the storage sub-circuit is shown in FIG. 4. It is easily understood by those skilled in the art that implementations of the storage sub-circuit are not limited thereto.

FIG. 5 is an equivalent circuit diagram of a node control sub-circuit in accordance with an exemplary embodiment. As shown in FIG. 5, in an exemplary embodiment, the node control sub-circuit may include a first transistor T1 and a second transistor T2.

As shown in FIG. 5, a control electrode of the first transistor T1 is electrically connected to the first clock signal terminal CK, a first electrode of the first transistor T1 is electrically connected to the signal input terminal IN, and a second electrode of the first transistor T1 is electrically connected to the first node N1; a control electrode of the second transistor T2 is electrically connected to the second clock signal terminal CB, a first electrode of the second transistor T2 is electrically connected to the first node N1, and a second electrode of the second transistor T2 is electrically connected to the second node N2.

An exemplary structure of the node control sub-circuit is shown in FIG. 5. It is easily understood by those skilled in the art that implementations of the node control sub-circuit are not limited thereto.

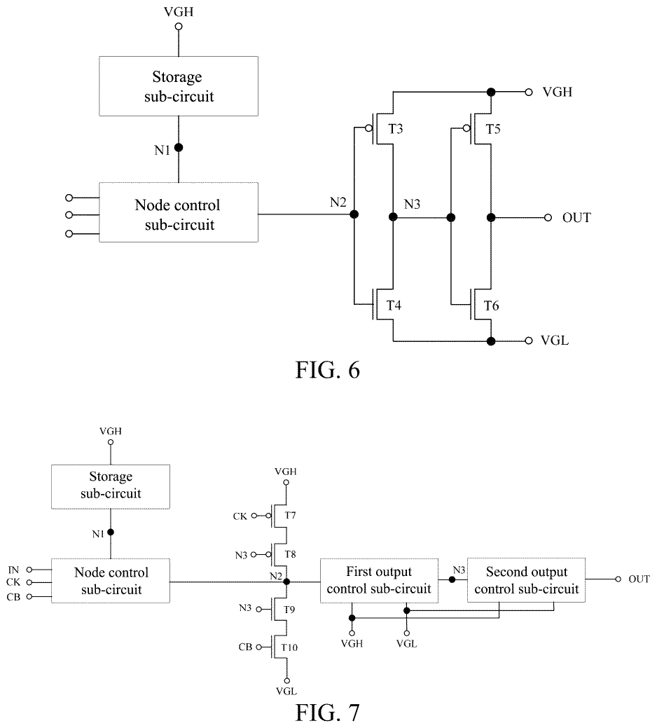

FIG. 6 is an equivalent circuit diagram of an output control sub-circuit in accordance with an exemplary embodiment. As shown in FIG. 6, in an exemplary embodiment, the first output control sub-circuit in the output control sub-circuit may include a third transistor T3 and a fourth transistor T4, and the second output control sub-circuit may include a fifth transistor T5 and a sixth transistor T6.

As shown in FIG. 6, a control electrode of the third transistor T3 is electrically connected to the second node N2, a first electrode of the third transistor T3 is electrically connected to the first power supply terminal VGH, and a second electrode of the third transistor T3 is electrically connected to the third node N3; a control electrode of the fourth transistor T4 is electrically connected to the second node N2, a first electrode of the fourth transistor is T4 electrically connected to the second power supply terminal VGL, and a second electrode of the fourth transistor T4 is electrically connected to the third node N3; a control electrode of the fifth transistor T5 is electrically connected to the third node N3, a first electrode of the fifth transistor T5 is electrically connected to the first power supply terminal VGH, and a second electrode of the fifth transistor T5 is electrically connected to the signal output terminal OUT; a control electrode of the sixth transistor T6 is electrically connected to the third node N3, a first electrode of the sixth transistor T6 is electrically connected to the second power supply terminal VGL, and a second electrode of the sixth transistor T6 is electrically connected to the signal output terminal OUT.

In the exemplary embodiment, the third transistor T3 and the fourth transistor T4 are of opposite types, i.e., the first output control sub-circuit is equivalent to a set of inverters. The fifth transistor T5 and the sixth transistor T6 are of opposite types, i.e., the second output control sub-circuit is equivalent to a set of inverters. The output control sub-circuit in accordance with the present disclosure is equivalent to two inverters in series.

An exemplary structure of the output control sub-circuit is shown in FIG. 6. It is easily understood by those skilled in the art that implementations of the output control sub-circuit are not limited thereto.

FIG. 7 is an equivalent circuit diagram of a noise reduction sub-circuit in accordance with an exemplary embodiment. As shown in FIG. 7, in an exemplary embodiment, the noise reduction sub-circuit may include a seventh transistor T7, an eighth transistor T8, a ninth transistor T9 and a tenth transistor T10.

As shown in FIG. 7, a control electrode of the seventh transistor T7 is electrically connected to the first clock signal terminal CK, a first electrode of the seventh transistor T7 is electrically connected to the first power supply terminal VGH, and a second electrode of the seventh transistor T7 is electrically connected to a first electrode of the eighth transistor T8; a control electrode of the eighth transistor T8 is electrically connected to the third node N3, and a second electrode of the eighth transistor T8 is electrically connected to the second node N2; a control electrode of the ninth transistor T9 is electrically connected to the third node N3, a first electrode of the ninth transistor T9 is electrically connected to the second node N2, and a second electrode of the ninth transistor T9 is electrically connected to a second electrode of the tenth transistor T10; a control electrode of the tenth transistor T10 is electrically connected to the second clock signal terminal CB, and a first electrode of the tenth transistor T10 is electrically connected to the second power supply terminal VGL.

In an exemplary embodiment, the seventh transistor T7 and the eighth transistor T8 may be of the same type.

In an exemplary embodiment, the ninth transistor T9 and the tenth transistor T10 may be of the same type.

In an exemplary embodiment, the seventh transistor T7 and the ninth transistor T9 may be of opposite types.

An exemplary structure of the noise reduction sub-circuit is shown in FIG. 7. It is easily understood by those skilled in the art that implementations of the noise reduction sub-circuit are not limited thereto.

In an exemplary embodiment, the transistor can be divided into an N-type transistor or a P-type transistor according to its characteristics. When the transistor is a P-type transistor, its turn-on voltage is a low-level voltage (e.g., 0V, −5V, −10V or other suitable voltages) and its turn-off voltage is a high-level voltage (e.g., 5V, 10V or other suitable voltages). When the transistor is an N-type transistor, its turn-on voltage is a high-level voltage (e.g., 5V, 10V or other suitable voltages) and its turn-off voltage is a low-level voltage (e.g., 0V, −5V, −10V or other suitable voltages).

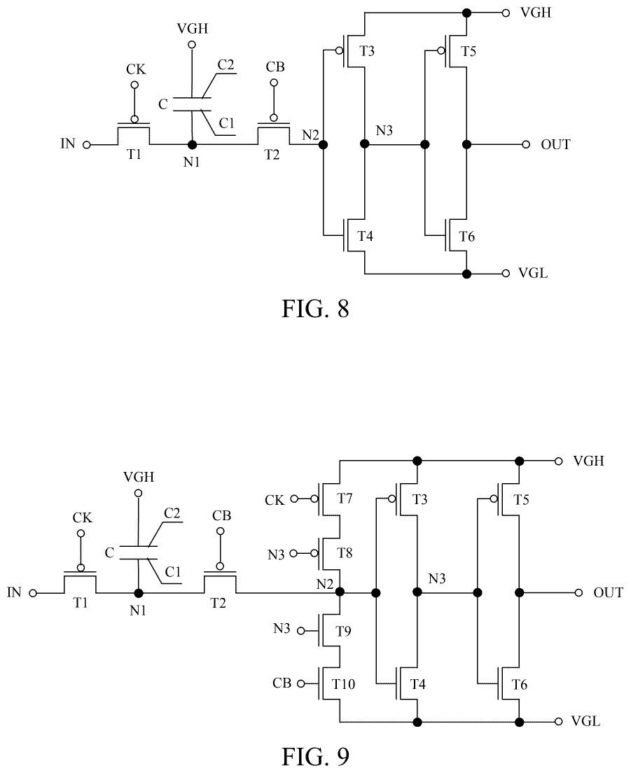

FIG. 8 is an equivalent circuit diagram of a shift register in accordance with an exemplary embodiment. As shown in FIG. 8, in an exemplary embodiment, the storage sub-circuit in the shift register may include a capacitor C including a first plate C1 and a second plate C2; the node control sub-circuit may include a first transistor T1 and a second transistor T2; the output control sub-circuit may include a third transistor T3, a fourth transistor T4, a fifth transistor T5 and a sixth transistor T6.

As shown in FIG. 8, the first plate C1 of the capacitor C is electrically connected to the first node N1, and the second plate C2 of the capacitor C is electrically connected to the first power supply terminal VGH; a control electrode of the first transistor T1 is electrically connected to the first clock signal terminal CK, a first electrode of the first transistor T1 is electrically connected to the signal input terminal IN, and a second electrode of the first transistor T1 is electrically connected to the first node N1; a control electrode of the second transistor T2 is electrically connected to the second clock signal terminal CB, a first electrode of the second transistor T2 is electrically connected to the first node N1, and a second electrode of the second transistor T2 is electrically connected to the second node N2; a control electrode of the third transistor T3 is electrically connected to the second node N2, a first electrode of the third transistor T3 is electrically connected to the first power supply terminal VGH, and a second electrode of the third transistor T3 is electrically connected to the third node N3; a control electrode of the fourth transistor T4 is electrically connected to the second node N2, a first electrode of the fourth transistor T4 is electrically connected to the second power supply terminal VGL, and a second electrode of the fourth transistor T4 is electrically connected to the third node N3; a control electrode of the fifth transistor T5 is electrically connected to the third node N3, a first electrode of the fifth transistor T5 is electrically connected to the first power supply terminal VGH, and a second electrode of the fifth transistor T5 is electrically connected to the signal output terminal OUT; a control electrode of the sixth transistor T6 is electrically connected to the third node N3, a first electrode of the sixth transistor T6 is electrically connected to the second power supply terminal VGL, and a second electrode of the sixth transistor T6 is electrically connected to the signal output terminal OUT.

In an exemplary embodiment, the first transistor T1, the second transistor T2, the third transistor T3 and the fifth transistor T5 may be P-type transistors.

In an exemplary embodiment, the fourth transistor T4 and the sixth transistor T6 may be N-type transistors and are oxide transistors. The oxide transistors can reduce leakage current, improve the performance of the shift register, and decrease the power consumption of the shift register.

FIG. 9 is an equivalent circuit diagram of a shift register in accordance with another exemplary embodiment. As shown in FIG. 9, in an exemplary embodiment, the shift register may further include a noise reduction sub-circuit; the storage sub-circuit may include a capacitor C including a first plate C1 and a second plate C2; the node control sub-circuit may include a first transistor T1 and a second transistor T2; the output control sub-circuit may include a third transistor T3, a fourth transistor T4, a fifth transistor T5 and a sixth transistor T6; the noise reduction sub-circuit may include a seventh transistor T7, an eighth transistor T8, a ninth transistor T9 and a tenth transistor T10.

As shown in FIG. 9, the first plate C1 of the capacitor C is electrically connected to the first node N1, and the second plate C2 of the capacitor C is electrically connected to the first power supply terminal VGH; a control electrode of the first transistor T1 is electrically connected to the first clock signal terminal CK, a first electrode of the first transistor T1 is electrically connected to the signal input terminal IN, and a second electrode of the first transistor T1 is electrically connected to the first node N1; a control electrode of the second transistor T2 is electrically connected to the second clock signal terminal CB, a first electrode of the second transistor T2 is electrically connected to the first node N1, and a second electrode of the second transistor T2 is electrically connected to the second node N2; a control electrode of the third transistor T3 is electrically connected to the second node N2, a first electrode of the third transistor T3 is electrically connected to the first power supply terminal VGH, and a second electrode of the third transistor T3 is electrically connected to the third node N3; a control electrode of the fourth transistor T4 is electrically connected to the second node N2, a first electrode of the fourth transistor T4 is electrically connected to the second power supply terminal VGL, and a second electrode of the fourth transistor T4 is electrically connected to the third node N3; a control electrode of the fifth transistor T5 is electrically connected to the third node N3, a first electrode of the fifth transistor T5 is electrically connected to the first power supply terminal VGH, and a second electrode of the fifth transistor T5 is electrically connected to the signal output terminal OUT; a control electrode of the sixth transistor T6 is electrically connected to the third node N3, a first electrode of the sixth transistor T6 is electrically connected to the second power supply terminal VGL, and a second electrode of the sixth transistor T6 is electrically connected to the signal output terminal OUT; a control electrode of the seventh transistor T7 is electrically connected to the first clock signal terminal CK, a first electrode of the seventh transistor T7 is electrically connected to the first power supply terminal VGH, and a second electrode of the seventh transistor T7 is electrically connected to a first electrode of the eighth transistor T8; a control electrode of the eighth transistor T8 is electrically connected to the third node N3, and a second electrode of the eighth transistor T8 is electrically connected to the second node N2; a control electrode of the ninth transistor T9 is electrically connected to the third node N3, a first electrode of the ninth transistor T9 is electrically connected to the second node N2, and a second electrode of the ninth transistor T9 is electrically connected to a second electrode of the tenth transistor T10; a control electrode of the tenth transistor T10 is electrically connected to the second clock signal terminal CB, and a first electrode of the tenth transistor T10 is electrically connected to the second power supply terminal VGL.

In an exemplary embodiment, the first transistor T1, the second transistor T2, the third transistor T3, the fifth transistor T5, the seventh transistor T7 and the eighth transistor T8 may be P-type transistors.

In an exemplary embodiment, the fourth transistor T4, the sixth transistor T6, the ninth transistor T9 and the tenth transistor T10 may be N-type transistors and are oxide transistors. The oxide transistors can reduce leakage current, improve the performance of the shift register, and decrease the power consumption of the shift register.

In an exemplary embodiment, a clock signal of the first clock signal terminal CK and a clock signal of the second clock signal terminal CB are signals which are inverted with respect to each other;

In an exemplary embodiment, the signal of the signal input terminal IN may be a first pulse signal, a signal of the signal output terminal OUT is a second pulse signal, a duration of the first pulse signal is equal to a period of the clock signal of the first clock signal terminal CK, a duration of the second pulse signal is equal to the duration of the first pulse signal, and start time of the second pulse signal is end time of the first pulse signal.

In an exemplary embodiment, the signal of the signal input terminal IN may be a third pulse signal, a duration of which is equal to N times the period of the clock signal of the first clock signal terminal CK, N being a positive integer greater than or equal to 2; the signal of the signal output terminal OUT may be a fourth pulse signal, a duration of which is equal to the duration of the third pulse signal, a difference between start time of the fourth pulse signal and start time of the third pulse signal being equal to the period of the clock signal of the first clock signal terminal CK.

The shift register in accordance with the present disclosure includes one capacitor only, and the quantity of transistors is relatively small, so that the area occupied by the shift register is reduced, and the power consumption is decreased.

The shift register in accordance with the present disclosure can output not only pulse signals with shorter duration but also signals with longer duration, that is, it can output various waveforms and has a wider applicable range.

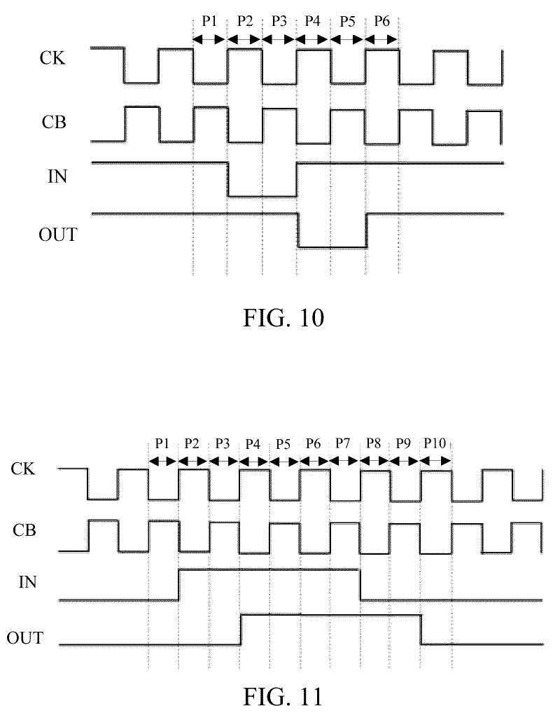

FIG. 10 is a working sequence diagram of a shift register in accordance with an exemplary embodiment, and FIG. 11 is a working sequence diagram of a shift register in accordance with another exemplary embodiment. Both FIG. 10 and FIG. 11 can be applicable to the shift registers shown in FIG. 8 and FIG. 9. FIG. 10 is illustrated by taking the shift register outputting pulse signals with shorter duration as an example, and FIG. 11 is illustrated by taking the shift register outputting pulse signals with longer duration as an example.

The exemplary embodiment of the present disclosure will be described below with reference to a working process of the shift register illustrated in FIG. 8. Taking the first transistor T1, the second transistor T2, the third transistor T3 and the fifth transistor T5 in the shift register provided in FIG. 8 being P-type transistors and the fourth transistor T4 and the sixth transistor T6 being N-type transistors as an example, the shift register in FIG. 8 includes the first transistors T1 through the sixth transistors T6, one capacitor (the capacitor C) and four signal terminals (the first clock signal terminal CK, the second clock signal terminal CB, the signal input terminal IN and the signal output terminal OUT).

In the exemplary embodiment, as shown in FIG. 10, the working process of the shift register provided in FIG. 8 may include the following stages.

In a first stage P1, the signal of the first clock signal terminal CK is a low-level signal, and the signals of the signal input terminal IN and the second clock signal terminal CB are high-level signals. The signal of the first clock signal terminal CK is a low-level signal, the first transistor T1 is turned on, the high-level signal of the signal input terminal IN is transmitted to the first node N1 through the turned-on first transistor T1, the signal of the second clock signal terminal CB is a high-level signal, the second transistor T2 is turned off, the signal of the second node N2 remains to be the high-level signal, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, a signal of the third node N3 is a low-level signal, and the signal of the signal output terminal OUT is a high-level signal.

In a second stage P2, the signal of the first clock signal terminal CK is a high-level signal, and the signals of the signal input terminal IN and the second clock signal terminal CB are low-level signals. The signal of the first clock signal terminal CK is a high-level signal, the first transistor T1 is turned off, the low-level signal of the signal input terminal IN cannot be transmitted to the first node N1, the first node N1 maintains the high-level signal of the previous stage, the signal of the second clock signal terminal CB is a low-level signal, the second transistor T2 is turned on, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a third stage P3, the signals of the first clock signal terminal CK and the signal input terminal IN are low-level signals, and the signal of the second clock signal terminal CB is a high-level signal. The signal of the first clock signal terminal CK is a low-level signal, the first transistor T1 is turned on, the low-level signal of the signal input terminal IN is transmitted to the first node N1 through the turned-on first transistor T1, the signal of the second clock signal terminal CB is a high-level signal, the second transistor T2 is turned off, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a low-level signal, the signal of the second node N2 is a high-level signal, the signal of the third node N3 is a low-level signal, and the signal of the signal output terminal OUT is a high-level signal.

In a fourth stage P4, the signals of the first clock signal terminal CK and the signal input terminal IN are high-level signals, and the signal of and the second clock signal terminal CB is a low-level signal. The signal of the first clock signal terminal CK is a high-level signal, the first transistor T1 is turned off, the high-level signal of the signal input terminal IN cannot be transmitted to the first node N1, the first node N1 maintains the low-level signal of the previous stage, the signal of the second clock signal terminal CB is a low-level signal, the second transistor T2 is turned on, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a fifth stage P5, the signal of the first clock signal terminal CK is a low-level signal, and the signals of the second clock signal terminal CB and the signal input terminal IN are high-level signals. The signal of the first clock signal terminal CK is a low-level signal, the first transistor T1 is turned on, the high-level signal of the signal input terminal IN is transmitted to the first node N1 through the turned-on first transistor T1, the signal of the second clock signal terminal CB is a high-level signal, the second transistor T2 is turned off, the second node N2 maintains the low-level signal of the previous stage, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node N1 is a high-level signal, the signal of the second node N2 is a low-level signal, the signal of the third node N3 is a high-level signal, and the signal of the signal output terminal OUT is a low-level signal.

In a sixth stage P6, the signals of the first clock signal terminal CK and the signal input terminal IN are high-level signals, and the signal of the second clock signal terminal CB is a low-level signal. The signal of the first clock signal terminal CK is a high-level signal, the first transistor T1 is turned off, the first node N1 maintains the high-level signal of the previous stage, the signal of the second clock signal terminal CB is a low-level signal, the second transistor T2 is turned on, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In an exemplary embodiment, as shown in FIG. 11, the working process of the shift register provided in FIG. 8 may include the following stages.

In a first stage P1, the signals of the first clock signal terminal CK and the signal input terminal IN are low-level signals, and the signal of the second clock signal terminal CB is a high-level signal. The signal of the first clock signal terminal CK is a low-level signal, the first transistor T1 is turned on, the low-level signal of the signal input terminal IN is transmitted to the first node N1 through the turned-on first transistor T1, the signal of the second clock signal terminal CB is a high-level signal, the second transistor T2 is turned off, the signal of the second node N2 remains to be the low-level signal, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a second stage P2, the signals of the first clock signal terminal CK and the signal input terminal IN are high-level signals, and the signal of the second clock signal terminal CB is a low-level signal. The signal of the first clock signal terminal CK is a high-level signal, the first transistor T1 is turned off, the high-level signal of the signal input terminal IN cannot be transmitted to the first node N1, the first node N1 maintains the low-level signal of the previous stage, the signal of the second clock signal terminal CB is a low-level signal, the second transistor T2 is turned on, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a third stage P3, the signal of the first clock signal terminal CK is a low-level signal, and the signals of the second clock signal terminal CB and the signal input terminal IN are high-level signals. The signal of the first clock signal terminal CK is a low-level signal, the first transistor T1 is turned on, the high-level signal of the signal input terminal IN is transmitted to the first node N1 through the turned-on first transistor T1, the signal of the second clock signal terminal CB is a high-level signal, the second transistor T2 is turned off, the second node N2 maintains the low-level signal of the previous stage, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node Nl is a high-level signal, the signal of the second node N2 is a low-level signal, the signal of the third node N3 is a high-level signal, and the signal of the signal output terminal OUT is a low-level signal.

In a fourth stage P4, the signals of the first clock signal terminal CK and the signal input terminal IN are high-level signals, and the signal of the second clock signal terminal CB is a low-level signal. The signal of the first clock signal terminal CK is a high-level signal, the first transistor T1 is turned off, the first node N1 maintains the high-level signal of the previous stage, the signal of the second clock signal terminal CB is a low-level signal, the second transistor T2 is turned on, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a fifth stage P5, the signal of the first clock signal terminal CK is a low-level signal, and the signals of the second clock signal terminal CB and the signal input terminal IN are high-level signals. The signal of the first clock signal terminal CK is a low-level signal, the first transistor T1 is turned on, the high-level signal of the signal input terminal IN is transmitted to the first node N1 through the turned-on first transistor T1, the signal of the second clock signal terminal CB is a high-level signal, the second transistor T2 is turned off, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a sixth stage P6, the signals of the first clock signal terminal CK and the signal input terminal IN are high-level signals, and the signal of and the second clock signal terminal CB is a low-level signal. The signal of the first clock signal terminal CK is a high-level signal, the first transistor T1 is turned off, the first node N1 maintains the high-level signal of the previous stage, the signal of the second clock signal terminal CB is a low-level signal, the second transistor T2 is turned on, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a seventh stage P7, the signal of the first clock signal terminal CK is a low-level signal, and the signals of the second clock signal terminal CB and the signal input terminal IN are high-level signals. The signal of the first clock signal terminal CK is a low-level signal, the first transistor T1 is turned on, the high-level signal of the signal input terminal IN is transmitted to the first node N1 through the turned-on first transistor T1, the signal of the second clock signal terminal CB is a high-level signal, the second transistor T2 is turned off, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In an eighth stage P8, the signal of the first clock signal terminal CK is a high-level signal, and the signals of the second clock signal terminal CB the signal input terminal IN are low-level signals. The signal of the first clock signal terminal CK is a high-level signal, the first transistor T1 is turned off, the low-level signal of the signal input terminal IN cannot be transmitted to the first node N1, the first node N1 maintains the high-level signal of the previous stage, the signal of the second clock signal terminal CB is a low-level signal, the second transistor T2 is turned on, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a ninth stage P9, the signals of the first clock signal terminal CK and the signal input terminal IN are low-level signals, and the signal of the second clock signal terminal CB is a high-level signal. The signal of the first clock signal terminal CK is a low-level signal, the first transistor T1 is turned on, the low-level signal of the signal input terminal IN is transmitted to the first node N1 through the turned-on first transistor T1, the signal of the second clock signal terminal CB is a high-level signal, the second transistor T2 is turned off, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 is turned on, and the high-level signal of the first power supply terminal VGH is transmitted to the signal output terminal OUT through the turned-on fifth transistor T5. In this stage, the signal of the first node NI is a low-level signal, the signal of the second node N2 is a high-level signal, the signal of the third node N3 is a low-level signal, and the signal of the signal output terminal OUT is a high-level signal.

In a tenth stage P10, the signal of the first clock signal terminal CK is a high-level signal, and the signals of the second clock signal terminal CB and the signal input terminal IN are low-level signals. The signal of the first clock signal terminal CK is a high-level signal, the first transistor T1 is turned off, the first node N1 maintains the low-level signal of the previous stage, the signal of the second clock signal terminal CB is a low-level signal, the second transistor T2 is turned on, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 is turned on, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

The exemplary embodiment of the present disclosure will be described below with reference to a working process of the shift register illustrated in FIG. 9. Taking the first transistor T1, the second transistor T2, the third transistor T3, the fifth transistor T5, the seventh transistor T7 and eighth transistor T8 in the shift register provided in FIG. 9 being P-type transistors and the fourth transistor T4, the sixth transistor T6, the ninth transistor T9 and the tenth transistor T10 being N-type transistors as an example, the shift register in FIG. 9 includes the first transistors T1 through the tenth transistors T10, one capacitor (the capacitor C) and four signal terminals (the first clock signal terminal CK, the second clock signal terminal CB, the signal input terminal IN and the signal output terminal OUT).

In an exemplary embodiment, as shown in FIG. 10, the working process of the shift register provided in FIG. 9 may include the following stages.

In a first stage P1, the signal of the first clock signal terminal CK is a low-level signal, and the signals of the signal input terminal IN and the second clock signal terminal CB are high-level signals. The signal of the first clock signal terminal CK is a low-level signal, the first transistor T1 and the seventh transistor T7 are turned on, the high-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the signal of the second node N2 remains to be the high-level signal, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because the ninth transistor T9 is turned off, the low-level signal of the second power supply terminal VGL cannot be written to the second node N2, the signal of the first power supply terminal VGH can be transmitted to the second node N2 through the turned-on seventh transistor T7 and the eighth transistor T8, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a second stage P2, the signal of the first clock signal terminal CK is a high-level signal, and the signals of the signal input terminal IN and the second clock signal terminal CB are low-level signals. The signal of the first clock signal terminal CK is a high-level signal, the first transistor T1 and the seventh transistor T7 are turned off, the low-level signal of the signal input terminal IN cannot be transmitted to the first node N1, the first node N1 maintains the high-level signal of the previous stage, the signal of the second clock signal terminal CB is a low-level signal, the second transistor T2 is turned on, the tenth transistor T10 is turned off, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because both the ninth transistor T9 and the tenth transistor T10 are turned off, the low-level signal of the second power supply terminal VGL cannot be written to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a third stage P3, the signals of the first clock signal terminal CK and the signal input terminal IN are low-level signals, and the signal of the second clock signal terminal CB is a high-level signal. The signal of the first clock signal terminal CK is a low-level signal, the first transistor T1 and the seventh transistor T7 are turned on, the low-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because the ninth transistor T9 is turned off, the low-level signal of the second power supply terminal VGL cannot be written to the second node N2, the signal of the first power supply terminal VGH can be transmitted to the second node N2 through the turned-on seventh transistor T7 and eighth transistor T8, the signal of the second node N2 remains to be the high-level signal, and the high-level signal of the first power supply terminal VGH is transmitted to the signal output terminal OUT through the turned-on fifth transistor T5. In this stage, the signal of the first node N1 is a low-level signal, the signal of the second node N2 is a high-level signal, the signal of the third node N3 is a low-level signal, and the signal of the signal output terminal OUT is a high-level signal.

In a fourth stage P4, the signals of the first clock signal terminal CK and the signal input terminal IN are high-level signals, and the signal of the second clock signal terminal CB is a low-level signal. The signal of the first clock signal terminal CK is a high-level signal, the first transistor T1 and the seventh transistor T7 are turned off, the high-level signal of the signal input terminal IN cannot be transmitted to the first node N1, the first node N1 maintains the low-level signal of the previous stage, the signal of the second clock signal terminal CB is a low-level signal, the second transistor T2 is turned on, the tenth transistor T10 is turned off, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 and the ninth transistor T9 are turned on, and the eighth transistor T8 is turned off. Because both the seventh transistor T7 and the eighth transistor T8 are turned off, the high-level signal of the first power supply terminal VGH cannot be written to the second node N2, the signal of the second node N2 remains to be the low-level signal, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a fifth stage P5, the signal of the first clock signal terminal CK is a low-level signal, and the signals of the second clock signal terminal CB and the signal input terminal IN are high-level signals. The signal of the first clock signal terminal CK is a low-level signal, the first transistor T1 and the seventh transistor T7 are turned on, the high-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the second node N2 maintains the low-level signal of the previous stage, the third transistor T3 is turned on, the high-level signal of the first power supply terminal VGH is transmitted to the third node N3 through the turned-on third transistor T3, the sixth transistor T6 and the ninth transistor T9 are turned on, and the eighth transistor T8 is turned off. Because the ninth transistor T9 and the tenth transistor T10 are turned on, the low-level signal of the second power supply terminal VLG is transmitted to the second node N2 through the turned-on ninth transistor T9 and tenth transistor T10, the signal of the second node N2 remains to be the low-level signal, and the low-level signal of the second power supply terminal VGL is transmitted to the signal output terminal OUT through the turned-on sixth transistor T6. In this stage, the signal of the first node N1 is a high-level signal, the signal of the second node N2 is a low-level signal, the signal of the third node N3 is a high-level signal, and the signal of the signal output terminal OUT is a low-level signal.

In a sixth stage P6, the signals of the first clock signal terminal CK and the signal input terminal IN are high-level signals, and the signal of the second clock signal terminal CB is a low-level signal. The signal of the first clock signal terminal CK is a high-level signal, the first transistor T1 and the seventh transistor T7 are turned off, the first node N1 maintains the high-level signal of the previous stage, the signal of the second clock signal terminal CB is a low-level signal, the second transistor T2 is turned on, the tenth transistor T10 is turned off, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because both the ninth transistor T9 and the tenth transistor T10 are turned off, the low-level signal of the second power supply terminal VLG cannot be transmitted to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In an exemplary embodiment, as shown in FIG. 11, the working process of the shift register provided in FIG. 9 may include the following stages.

In a first stage P1, the signals of the first clock signal terminal CK and the signal input terminal IN are low-level signals, and the signal of and the second clock signal terminal CB is a high-level signal. The signal of the first clock signal terminal CK is a low-level signal, the first transistor T1 and the seventh transistor T7 are turned on, the low-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the signal of the second node N2 remains to be the low-level signal, the third transistor T3 is turned on, the high-level signal of the first power supply terminal VGH is transmitted to the third node N3 through the turned-on third transistor T3, the sixth transistor T6 and the ninth transistor T9 are turned on, the eighth transistor T8 is turned off, the low-level signal of the second power supply terminal VGL is transmitted to the second node N2 through the turned-on ninth transistor T9 and tenth transistor T10, the signal of the second node N2 remains to be the low-level signal, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a second stage P2, the signals of the first clock signal terminal CK and the signal input terminal IN are high-level signals, and the signal of the second clock signal terminal CB is a low-level signal. The signal of the first clock signal terminal CK is a high-level signal, the first transistor T1 and the seventh transistor T7 are turned off, the high-level signal of the signal input terminal IN cannot be transmitted to the first node N1, the first node N1 maintains the low-level signal of the previous stage, the signal of the second clock signal terminal CB is a low-level signal, the second transistor T2 is turned on, the tenth transistor T10 is turned off, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 and the ninth transistor T9 are turned on, and the eighth transistor T8 is turned off. Because both the seventh transistor T7 and the eighth transistor T8 are turned off, the high-level signal of the first power supply terminal VGH cannot be transmitted to the second node N2, the signal of the second node N2 remains to be the low-level signal, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

In a third stage P3, the signal of the first clock signal terminal CK is a low-level signal, and signals of the second clock signal terminal CB and the signal input terminal IN are high-level signals. The signal of the first clock signal terminal CK is a low-level signal, the first transistor T1 and the seventh transistor T7 are turned on, the high-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the second node N2 maintains the low-level signal of the previous stage, the third transistor T3 is turned on, the high-level signal of the first power supply terminal VGH is transmitted to the third node N3 through the turned-on third transistor T3, the sixth transistor T6 and the ninth transistor T9 are turned on, the eighth transistor T8 is turned off, the low-level signal of the second power supply terminal VGL is transmitted to the second node N2 through the turned-on ninth transistor T9 and tenth transistor T10, the signal of the second node N2 remains to be the low-level signal, and the low-level signal of the second power supply terminal VGL is transmitted to the signal output terminal OUT through the turned-on sixth transistor T6. In this stage, the signal of the first node N1 is a high-level signal, the signal of the second node N2 is a low-level signal, the signal of the third node N3 is a high-level signal, and the signal of the signal output terminal OUT is a low-level signal.

In a fourth stage P4, the signals of the first clock signal terminal CK and the signal input terminal IN are high-level signals, and the signal of the second clock signal terminal CB is a low-level signal. The signal of the first clock signal terminal CK is a high-level signal, the first transistor T1 and the seventh transistor T7 are turned off, the first node N1 maintains the high-level signal of the previous stage, the signal of the second clock signal terminal CB is a low-level signal, the second transistor T2 is turned on, the tenth transistor T10 is turned off, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because both the ninth transistor T9 and the tenth transistor T10 are turned off, the low-level signal of the second power supply terminal VGL cannot be transmitted to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a fifth stage P5, the signal of the first clock signal terminal CK is a low-level signal, and the signals of the second clock signal terminal CB and the signal input terminal IN are high-level signals. The signal of the first clock signal terminal CK is a low-level signal, the first transistor T1 and the seventh transistor T7 are turned on, the high-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the signal of the second node N2 remains to be the high-level signal of the previous stage, the fourth transistor T4 is turned on, the low-level signal of the second power supply terminal VGL is transmitted to the third node N3 through the turned-on fourth transistor T4, the fifth transistor T5 and the eighth transistor T8 are turned on, the ninth transistor T9 is turned off, the high-level signal of the first power supply terminal VGH is transmitted to the second node N2 through the turned-on seventh transistor T7 and eighth transistor T8, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a sixth stage P6, the signals of the first clock signal terminal CK and the signal input terminal IN are high-level signals, and the signal of the second clock signal terminal CB is a low-level signal. The signal of the first clock signal terminal CK is a high-level signal, the first transistor T1 and the seventh transistor T7 are turned off, the first node N1 maintains the high-level signal of the previous stage, the signal of the second clock signal terminal CB is a low-level signal, the second transistor T2 is turned on, the tenth transistor T10 is turned off, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because both the ninth transistor T9 and the tenth transistor T10 are turned off, the low-level signal of the second power supply terminal VGL cannot be transmitted to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a seventh stage P7, the signal of the first clock signal terminal CK is a low-level signal, and the signal of the second clock signal terminal CB and the signal input terminal IN are high-level signals. The signal of the first clock signal terminal CK is a low-level signal, the first transistor T1 and the seventh transistor T7 are turned on, the high-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 and the eighth transistor T8 are turned on, the ninth transistor T9 is turned off, the high-level signal of the first power supply terminal VGH is transmitted to the second node N2 through the turned-on seventh transistor T7 and eighth transistor T8, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In an eighth stage P8, the signal of the first clock signal terminal CK is a high-level signal, and the signals of the second clock signal terminal CB and the signal input terminal IN are low-level signals. The signal of the first clock signal terminal CK is a high-level signal, the first transistor T1 and the seventh transistor T7 are turned off, the low-level signal of the signal input terminal IN cannot be transmitted to the first node N1, the first node N1 maintains the high-level signal of the previous stage, the signal of the second clock signal terminal CB is a low-level signal, the second transistor T2 is turned on, the tenth transistor T10 is turned off, the high-level signal of the first node N1 is transmitted to the second node N2 through the turned-on second transistor T2, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because both the ninth transistor T9 and the tenth transistor T10 are turned off, the low-level signal of the second power supply terminal VGL cannot be transmitted to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a high-level signal, the signal of the second node N2 is a high-level signal, the signal of the third node N3 is a low-level signal, and the signal of the signal output terminal OUT is a high-level signal.

In a ninth stage P9, the signals of the first clock signal terminal CK and the signal input terminal IN are low-level signals, and the signal of the second clock signal terminal CB is a high-level signal. The signal of the first clock signal terminal CK is a low-level signal, the first transistor T1 and the seventh transistor T7 are turned on, the low-level signal of the signal input terminal IN is transmitted to the first node N1 through the turned-on first transistor T1, the signal of the second clock signal terminal CB is a high-level signal, the second transistor T2 is turned off, the tenth transistor T10 is turned on, the second node N2 maintains the high-level signal of the previous stage, the fourth transistor T4 is turned on, the low-level signal of the second power supply terminal VGL is transmitted to the third node N3 through the turned-on fourth transistor T4, the fifth transistor T5 and the eighth transistor T8 are turned on, and the ninth transistor T9 is turned off. Because the ninth transistor T9 is turned off, the low-level signal of the second power supply terminal VGL cannot be transmitted to the second node N2, the signal of the second node N2 remains to be the high-level signal, and the high-level signal of the first power supply terminal VGH is transmitted to the signal output terminal OUT through the turned-on fifth transistor T5. In this stage, the signal of the first node N1 is a low-level signal, the signal of the second node N2 is a high-level signal, the signal of the third node N3 is a low-level signal, and the signal of the signal output terminal OUT is a high-level signal.

In a tenth stage P10, the signal of the first clock signal terminal CK is a high-level signal, and the signals of the second clock signal terminal CB and the signal input terminal IN are low-level signals. The signal of the first clock signal terminal CK is a high-level signal, the first transistor T1 and the seventh transistor T7 are turned off, the first node N1 maintains the low-level signal of the previous stage, the signal of the second clock signal terminal CB is a low-level signal, the second transistor T2 is turned on, the tenth transistor T10 is turned off, the low-level signal of the first node N1 is transmitted to the second node N2 through the turned-on second transistor T2, the third transistor T3 is turned on, the high-level signal of the first power supply terminal VGH is transmitted to the third node N3 through the turned-on third transistor T3, the sixth transistor T6 and the ninth transistor T9 are turned on, and the eighth transistor T8 is turned off. Because both the seventh transistor T7 and the eighth transistor T8 are turned off, the high-level signal of the first power supply terminal VGH cannot be transmitted to the second node N2, the signal of the second node N2 remains to be the low-level signal, and the low-level signal of the second power supply terminal VGL is transmitted to the signal output terminal OUT through the turned-on sixth transistor T6. In this stage, the signal of the first node N1 is a low-level signal, the signal of the second node N2 is a low-level signal, the signal of the third node N3 is a high-level signal, and the signal of the signal output terminal OUT is a low-level signal.

The embodiment of the present disclosure further provides a display substrate including a display area and a non-display area. The display substrate includes a substrate and a circuit structure layer disposed on the substrate, the circuit structure layer includes a gate driving circuit located in the non-display area and a pixel circuit, which is arranged in an array, located in the display area, the gate driving circuit includes a plurality of cascaded shift registers, and the pixel circuit includes a light emitting signal line, a scan signal line and a reset signal line.

A signal output terminal of an i-th stage shift register is electrically connected to a signal input terminal of an (i+1)-th stage shift register, 1≤i≤M−1, and M being the total number of stages of the shift registers.

In the present disclosure, the gate driving circuit may be electrically connected to at least one of the light emitting signal line, the scan signal line and the reset signal line.

In an exemplary embodiment, the gate circuit may be a circuit structure of 7T1C or 8T1C, the present disclosure is not limited thereto.

The shift register may be the shift register in accordance with any one of the aforementioned embodiments, and its implementation principle and implementation effect are similar to the foresaid implementation principle and implementation effect and will not be repeated herein.

For different display products, cascade relationships of the plurality of shift registers in the gate driving circuit may be different. Regardless of the cascade relationships of the plurality of shift registers and no matter how many rows of sub-pixels are driven by each of the shift registers, as long as such a large-area device is changed and such a change generates additional space, both possible simple translation and stretching of a small device are within the protection scope of the present disclosure.

In the exemplary embodiment, the display substrate in accordance with the present disclosure may be applied to a display device with a gate driving circuit, such as an OLED, a quantum dot display (QLED), a light emitting diode display (Micro LED or Mini LED) or a quantum dot light emitting diode display (QDLED), etc., the present disclosure is not limited thereto.

In an exemplary embodiment, the circuit structure layer may further include the pixel circuit and the reset signal line, the light emitting signal line and the scan signal line which are connected to the pixel circuit. The gate driving circuit may provide signals to at least one of the reset signal line, the light emitting signal line and the scan signal line.

In an exemplary embodiment, the display substrate may further include a light emitting structure layer located on one side of the circuit structure layer away from the substrate. The light emitting structure layer includes light emitting elements, which are arranged in an array, located in the display area.

In an exemplary embodiment, the light emitting elements may be organic light emitting diodes (OLEDs) or quantum dot light emitting diodes (QLEDs). The OLED may include a first electrode (anode), an organic light emitting layer and a second electrode (cathode) that are stacked.

In an exemplary embodiment, the display substrate may further include other film layers, such as post spacers, the present disclosure is not limited thereto.

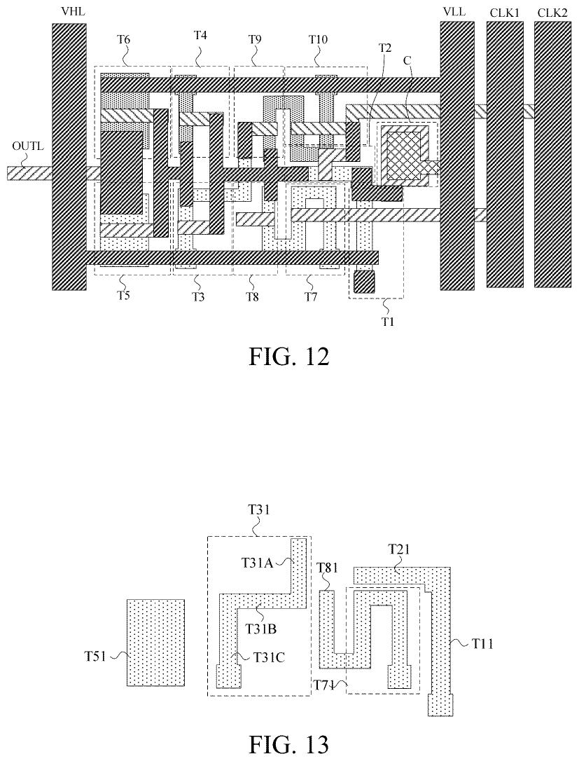

FIG. 12 is a schematic structural diagram of a display substrate in accordance with an exemplary embodiment. As shown in FIG. 12, In an exemplary embodiment, the display substrate may further include a first clock signal line CLK1, a second clock signal line CLK2, a first power supply line VHL and a second power supply line VLL extending along a first direction, the first power supply line VHL, the second power supply line VLL, the first clock signal line CLK1 and the second clock signal line CLK2 being arranged along a second direction, and the first direction intersecting the second direction.

First power supply terminals of all the shift registers are electrically connected to the first power supply line, second power supply terminals of all the shift registers are electrically connected to the second power supply line, a first clock signal terminal of the i-th stage shift register is electrically connected to the first clock signal line, a second clock signal terminal of the i-th stage shift register is electrically connected to the second clock signal line, a first clock signal terminal of the (i+1)-th stage shift register is electrically connected to the second clock signal line, and a second clock signal terminal of the (i+1)-th stage shift register is electrically connected to the first clock signal line.

As shown in FIG. 12, each of the shift registers includes a first transistor T1 through a tenth transistor T10 and a capacitor C including a first plate and a second plate.

In the exemplary embodiment, the circuit structure layer may include a first semiconductor layer, a first insulating layer, a first conductive layer, a second insulating layer, a second conductive layer, a third insulating layer, a second semiconductor layer, a fourth insulating layer, a third conductive layer, a fifth insulating layer and a fourth conductive layer which are sequentially stacked on the substrate.

The first semiconductor layer includes an active layer of the first transistor, an active layer of the second transistor, an active layer of the third transistor, an active layer of the fifth transistor, an active layer of the seventh transistor and an active layer of the eighth transistor.

The first conductive layer includes a control electrode of the first transistor, a control electrode of the second transistor, a control electrode of the third transistor, a control electrode of the fifth transistor, a control electrode of the seventh transistor, a control electrode of the eighth transistor, the first plate of the capacitor and a signal output line.

The second conductive layer includes the second plate of the capacitor.

The second semiconductor layer includes an active layer of the fourth transistor, an active layer of the sixth transistor, an active layer of the ninth transistor and an active layer of the tenth transistor.

The third conductive layer includes a control electrode of the fourth transistor, a control electrode of the sixth transistor, a control electrode of the ninth transistor and a control electrode of the tenth transistor.

The fourth conductive layer includes the first clock signal line, the second clock signal line, the first power supply line, the second power supply line, first electrodes and second electrodes of the first transistor through the sixth transistor, a first electrode of the seventh transistor, a second electrode of the eighth transistor, a first electrode of the ninth transistor, a first electrode of the tenth transistor, a first connection signal line, a second connection signal line and a third connection signal line.

The signal output line is connected to the second electrode of the fifth transistor and the second electrode of the sixth transistor respectively; the first connection signal line is connected to the active layer of the third transistor and the control electrode of the ninth transistor respectively; the second connection signal line is connected to the active layer of the third transistor and the control electrode of the eighth transistor respectively; the third connection signal line is connected to the control electrode of the tenth transistor and the control electrode of the second transistor respectively.

As shown in FIG. 12, in an exemplary embodiment, the fifth transistor T5 and the sixth transistor T6 are located at the same side of the first power supply line VHL, and the fifth transistor T5 and the sixth transistor T6 are arranged along the first direction; the third transistor T3 is located at one side of the fifth transistor T5 away from the first power supply line VHL, the fourth transistor T4 is located at one side of the sixth transistor T6 away from the first power supply line VHL, the third transistor T3 and the fourth transistor T4 are arranged along the first direction, the third transistor T3 and the fifth transistor T5 are arranged along the second direction, and the fourth transistor T4 and the sixth transistor T6 are arranged along the second direction; the eighth transistor T8 is located at one side of the third transistor T3 away from the fifth transistor T5, the ninth transistor T9 is located at one side of the fourth transistor T4 away from the sixth transistor T6, the eighth transistor T8 and the ninth transistor T9 are arranged along the first direction, the third transistor T3 and the eighth transistor T8 are arranged along the second direction, and the fourth transistor T4 and the ninth transistor T9 are arranged along the second direction; the seventh transistor T7 is located at one side of the eighth transistor T8 away from the third transistor T3, the tenth transistor T10 is located at one side of the ninth transistor T9 away from the fourth transistor T4, the seventh transistor T7 and the tenth transistor T10 are arranged along the first direction, the seventh transistor T7 and the eighth transistor T8 are arranged along the second direction, and the ninth transistor T9 and the tenth transistor T10 are arranged along the second direction; the second transistor T2 is located between the seventh transistor T7 and the tenth transistor T10, the first transistor T1 is located at one side of the seventh transistor T7 away from the eighth transistor T8, and the capacitor C is located at one side of the tenth transistor T10 away from the ninth transistor T9; the second power supply line VLL is located at one side of the capacitor C away from the tenth transistor T10, the first clock signal line CLK1 is located at one side of the second power supply line VLL away from the capacitor C, and the second clock signal line CLK2 is located at one side of the first clock signal line CLK1 away from the second power supply line VLL.

In an exemplary embodiment, the active layer of the first transistor and the active layer of the second transistor form an integrated structure, and the active layer of the seventh transistor and the active layer of the eighth transistor form an integrated structure.

The active layer of the third transistor includes a first active connection part, a second active connection part and a third active connection part, wherein the first active connection part and the third active connection part extend along the first direction, and the second active connection part extends along the second direction and is connected to the first active connection part and the third active connection part respectively.

The first active connection part is located at one side of the second active connection part close to the integrated structure of the active layer of the seventh transistor and the active layer of the eighth transistor, and the third active connection part is located at one side of the second active connection part away from the integrated structure of the active layer of the seventh transistor and the active layer of the eighth transistor.

A straight line extending along the second direction passes through the first active connection part and the active layer of the second transistor.

A straight line extending along the second direction passes through the third active connection part and the active layer of the first transistor.

In an exemplary embodiment, the first plate of the capacitor includes a first capacitor body part and a first capacitor connection part connected to each other.

The control electrode of the first transistor and the control electrode of the seventh transistor form an integrated structure, and are located at one side of the first capacitor connection part away from the first capacitor body part.

A virtual straight line extending along the second direction passes through the control electrode of the eighth transistor and the integrated structure of the control electrode of the first transistor and the control electrode of the seventh transistor.

A virtual straight line extending along the second direction passes through the control electrode of the third transistor and the control electrode of the eighth transistor.

A virtual straight line extending along the second direction passes through the control electrode of the fifth transistor and the control electrode of the third transistor.

A virtual straight line extending along the second direction passes through the signal output line and the control electrode of the second transistor.

In an exemplary embodiment, the second plate of the capacitor includes a second capacitor body part and a second capacitor connection part connected to each other, the second capacitor connection part being located at one side of the second capacitor body part.

The area of the first capacitor body part of the first plate of the capacitor is greater than the area of the second capacitor body part of the second plate of the capacitor.

Orthographic projections of the second capacitor body part and the second capacitor connection part on the substrate at least partially overlap with an orthographic projection of the first capacitor body part of the first plate of the capacitor on the substrate, and do not overlap with an orthographic projection of the first capacitor connection part of the first plate of the capacitor on the substrate.

In an exemplary embodiment, an orthographic projection of the active layer of the sixth transistor on the substrate and an orthographic projection of the active layer of the fifth transistor on the substrate are located at two opposite sides of an orthographic projection of the signal output line on the substrate respectively, and a straight line extending along the first direction passes through the active layer of the fifth transistor and the active layer of the sixth transistor.

The straight line extending along the first direction passes through the active layer of the fourth transistor and the third active connection part of the active layer of the third transistor.

A straight line extending along the first direction passes through the active layer of the ninth transistor and the active layer of the eighth transistor, and a straight line extending along the first direction passes through the active layer of the tenth transistor and the active layer of the seventh transistor.

In an exemplary embodiment, a virtual straight line extending along the second direction passes through the control electrode of the fourth transistor, the control electrode of the sixth transistor and the control electrode of the ninth transistor.

The control electrode of the tenth transistor includes a first electrode connection part, a second electrode connection part and a third electrode connection part. The first electrode connection part and the third electrode connection part extend along the second direction, and the second electrode connection part extends along the first direction and is connected to the first electrode connection part and the third electrode connection part respectively.

The first electrode connection part is located at one side of the second electrode connection part close to the control electrode of the ninth transistor, and the third electrode connection part is located at one side of the second electrode connection part away from the control electrode of the ninth transistor.

A virtual straight line extending along the second direction passes through an orthographic projection of the first electrode connection part of the control electrode of the tenth transistor on the substrate and the orthographic projection of the first capacitor body part of the first plate of the capacitor on the substrate.

An orthographic projection of the third electrode connection part of the control electrode of the tenth transistor on the substrate is located at one side of an orthographic projection of the first plate of the capacitor on the substrate away from an orthographic projection of the integrated structure of the control electrode of the first transistor and the control electrode of the seventh transistor on the substrate.

In an exemplary embodiment, a pattern of a plurality of via holes is provided in the fifth insulating layer, wherein the pattern of the plurality of via holes includes first via hole through sixth via hole provided in the first insulating layer, the second insulating layer and the fifth insulating layer, seventh via hole through thirteenth via hole provided in the second insulating layer through fifth insulating layer, a fourteenth via hole provided in the third insulating layer through fifth insulating layer, fifteenth via hole through eighteenth via hole provided in the fourth insulating layer and fifth insulating layer, and nineteenth via hole through twenty-second via hole provided in the fifth insulating layer; the third via holes expose the active layer of the third transistor, and the twenty-second via holes expose the control electrode of the tenth transistor.

The quantity of the third via holes is four, a virtual straight line extending along the first direction passes through the first one of the third via holes and the second one of the third via holes, and the first one of the third via holes and the second one of the third via holes expose the first active connection part of the active layer of the third transistor, a virtual straight line extending along the first direction passes through the third one of the third via holes and the fourth one of the third via holes, the third one of the third via holes and the fourth one of the third via holes expose the third active connection part of the active layer of the third transistor, and a virtual straight line extending along the second direction passes through the second one of the third via holes and the third one of the third via holes.

The quantity of the twenty-second via holes is two, the first one of the twenty-second via holes exposes the second electrode connection part of the control electrode of the tenth transistor, and the second one of the twenty-second via holes exposes the third electrode connection part of the control electrode of the tenth transistor.

In an exemplary embodiment, the first electrode of the third transistor, the first electrode of the fifth transistor, the first electrode of the seventh transistor and the first power supply line form an integrated structure, the first electrode of the fourth transistor, the first electrode of the sixth transistor, the first electrode of the tenth transistor and the second power supply line form an integrated structure, the second electrode of the first transistor and the first electrode of the second transistor form an integrated structure, the second electrode of the third transistor and the second electrode of the fourth transistor form an integrated structure, the second electrode of the second transistor, the second electrode of the eighth transistor and the first electrode of the ninth transistor form an integrated structure, and the second electrode of the fifth transistor and the second electrode of the sixth transistor form an integrated structure.

An orthographic projection of the first power supply line on the substrate overlaps at least partially with the orthographic projection of the signal output line on the substrate; an orthographic projection of the second power supply line on the substrate overlaps partially with an orthographic projection of the integrated structure of the control electrode of the first transistor and the control electrode of the seventh transistor, an orthographic projection of the control electrode of the tenth transistor and an orthographic projection of the second capacitor connection part of the second plate of the capacitor on the substrate; an orthographic projection of the first clock signal line on the substrate overlaps partially with orthographic projections of the control electrode of the tenth transistor and the integrated structure of the control electrode of the first transistor and the control electrode of the seventh transistor on the substrate; an orthographic projection of the second clock signal line overlaps partially with an orthographic projection of the control electrode of the transistor, to which the second clock signal line is connected, on the substrate; an orthographic projection of the integrated structure of the second electrode of the first transistor and the first electrode of the second transistor on the substrate overlaps partially with the orthographic projection of the first capacitor connection part of the first plate of the capacitor on the substrate; an orthographic projection of the integrated structure of the second electrode of the third transistor and the second electrode of the fourth transistor on the substrate overlaps partially with orthographic projections of the control electrode of the sixth transistor and the control electrode of the fifth transistor on the substrate; an orthographic projection of the integrated structure of the second electrode of the fifth transistor and the second electrode of the sixth transistor on the substrate overlaps partially with the orthographic projection of the signal output line on the substrate; an orthographic projection of the integrated structure of the second electrode of the second transistor, the second electrode of the eighth transistor and the first electrode of the ninth transistor on the substrate overlaps partially with orthographic projections of the control electrode of the third transistor and the control electrode of the fourth transistor on the substrate; an orthographic projection of the first connection signal line on the substrate overlaps partially with an orthographic projection of the control electrode of the ninth transistor on the substrate; an orthographic projection of the second connection signal line on the substrate overlaps partially with an orthographic projection of the control electrode of the eighth transistor on the substrate; an orthographic projection of the third connection signal line on the substrate overlaps partially with orthographic projections of the control electrode of the second transistor and the control electrode of the tenth transistor on the substrate.

In an exemplary embodiment, the first electrode and the second electrode of the third transistor are connected to the active layer of the third transistor through the third one of the third via holes and the fourth one of the third via holes respectively; the first connection signal line is connected to the active layer of the third transistor through the first one of the third via holes; the second connection signal line is connected to the active layer of the third transistor through the second one of the third via holes; the third connection signal line is connected to the control electrode of the tenth transistor through the first one of the twenty-second via holes; one of the first clock signal line and the second clock signal line is connected to the control electrode of the tenth transistor through the second one of the twenty-second via holes.

A manufacturing process of the display substrate will be described below by way of embodiment. “Patterning processes” mentioned in the present disclosure include photoresist coating, mask exposure, development, etching, photoresist stripping, etc., for metal materials, inorganic materials or transparent conductive materials, and include organic material coating, mask exposure, development, etc., for organic materials. Deposition may be any one or more of sputtering, evaporation and chemical vapor deposition, coating may be any one or more of spray coating, spin coating and inkjet printing, and etching may be any one or more of dry etching and wet etching, the present disclosure is not limited thereto. “Film” refers to a layer of film formed from a certain material on a substrate using deposition, coating or other processes. If the “film” does not need to be processed through the patterning processes in the entire manufacturing process, the “film” may also be called a “layer”. If the “film” needs to be processed through the patterning processes in the entire manufacturing process, the “film” is called a “film” before the patterning processes are performed and is called a “layer” after the patterning processes are performed. At least one “pattern” is contained in the “layer” which has been processed through the patterning processes. “A and B being disposed on the same layer” mentioned in the present disclosure means that A and B are formed simultaneously through the same running of the patterning processes, and the “thickness” of the film layer is the dimension of the film layer in a direction perpendicular to the display substrate. In an exemplary embodiment of the present disclosure, “an orthographic projection of B being within the range of an orthographic projection of A” or “an orthographic projection of A containing an orthographic projection of B” means that the boundary of the orthographic projection of B falls within the range of the boundary of the orthographic projection of A, or the boundary of the orthographic projection of A overlaps with the boundary of the orthographic projection of B. FIGS. 13 to 18 are illustrated by taking the display substrate including the shift register provided in FIG. 9, that is, the shift register including the first transistor T1 through the tenth transistor T10, as an example.

(1) Forming a pattern of a first semiconductor layer on a substrate, which includes: depositing a first semiconductor film on the substrate, and patterning the first semiconductor film through the patterning processes to form the patterns of the first semiconductor layer, as shown in FIG. 13. FIG. 13 is a schematic diagram after a pattern of the first semiconductor layer is formed.

In an exemplary embodiment, as shown in FIG. 13, the pattern of the first semiconductor layer may include an active layer T11 of a first transistor, an active layer T21 of a second transistor, an active layer T31 of a third transistor, an active layer T51 of a fifth transistor, an active layer T71 of a seventh transistor T7 and an active layer T81 of an eighth transistor T8.

In an exemplary embodiment, the substrate may be a rigid substrate or a flexible substrate. The rigid substrate may be, but be not limited to, one or more of glass and metal foil; the flexible substrate may be, but be not limited to, one or more of polyethylene terephthalate, ethylene terephthalate, polyether ether ketone, polystyrene, polycarbonate, polyarylate, polyarylester, polyimide, polyvinyl chloride, polyethylene and textile fibers.

In an exemplary embodiment, the flexible substrate may include a first flexible material layer, a first inorganic material layer, a semiconductor layer, a second flexible material layer and a second inorganic material layer which are stacked. Materials of the first flexible material layer and second flexible material layer may be polyimide (PI), polyethylene terephthalate (PET) or surface treated polymer soft films, and materials of the first inorganic material layer and second inorganic material layer may be silicon nitride (SiNx) or silicon oxide (SiOx), for improving the water and oxygen resistance performance of the substrate. The first inorganic material layer and second inorganic material layer may also be referred to as barrier layers. A material of the semiconductor layer may be amorphous silicon (a-si). In an exemplary embodiment, taking a stacked structure of PI1/Barrier1/a-si/PI2/Barrier2 as an example, its manufacturing process may include: first coating a layer of polyimide on a glass carrier board, after the layer of polyimide is cured to form a film, a first flexible (PI1) layer is formed; then depositing a layer of barrier film on the first flexible layer to form a first barrier (Barrier 1) layer overlaying the first flexible layer; then depositing a layer of amorphous silicon film on the first barrier layer to form an amorphous silicon (a-si) layer overlaying the first barrier layer; then coating another layer of polyimide on the amorphous silicon layer, after this layer of polyimide is cured to form a film, a second flexible (PI2) layer is formed; and then depositing a layer of barrier film on the second flexible layer to form a second barrier (Barrier 2) layer overlaying the second flexible layer, so as to complete the substrate manufacturing.

In an exemplary embodiment, the first semiconductor layer may be made of various materials, such as amorphous indium gallium zinc oxide (a-IGZO), zinc oxynitride (ZnON), indium zinc tin oxide (IZTO), amorphous silicon (a-Si), polycrystalline silicon (p-Si), sexithiophene and polythiophene, that is, the present disclosure is applicable to transistors manufactured based on oxide technology, silicon technology and organic matter technology.

In an exemplary embodiment, as shown in FIG. 13, the active layer T11 of the first transistor and the active layer T21 of the second transistor may form an integrated structure, and the active layer T71 of the seventh transistor and the active layer T81 of the eighth transistor may form an integrated structure.

In an exemplary embodiment, as shown in FIG. 13, the active layer T11 of the first transistor extends along the first direction and may be a strip-shaped structure, and the active layer T21 of the second transistor extends along the second direction and may be a strip-shaped structure. The integrated structure of the active layer T11 of the first transistor and the active layer T21 of the second transistor may be in the shape of an “inverted L”, an opening of “inverted L” faces the integrated structure of the active layer T71 of the seventh transistor and the active layer T81 of the eighth transistor.

In an exemplary embodiment, as shown in FIG. 13, the active layer T71 of the seventh transistor may be n-shaped, and the active layer T81 of the eighth transistor may be L-shaped. The integrated structure of the active layer T71 of the seventh transistor and the active layer T81 of the eighth transistor may be in the shape of an “S” rotated by 90 degrees.

In an exemplary embodiment, as shown in FIG. 13, the active layer T31 of the third transistor may be located at one side of the integrated structure of the active layer T71 of the seventh transistor and the active layer T81 of the eighth transistor away from the integrated structure of the active layer T11 of the first transistor and the active layer T21 of the second transistor.

In an exemplary embodiment, as shown in FIG. 13, the active layer T31 of the third transistor may include a first active connection part T31A, a second active connection part T31B and a third active connection part T31C. The first active connection part T31A and the third active connection part T31C extend along the first direction, and the second active connection part T31B extends along the second direction and is connected to the first active connection part T31A and the third active connection part T31C respectively.

In an exemplary embodiment, as shown in FIG. 13, the first active connection part T31A and the third active connection part T31C are located at two opposite sides of the second active connection part T31B respectively. The first active connection part T31A is located at one side of the second active connection part T31B close to the integrated structure of the active layer T71 of the seventh transistor and the active layer T81 of the eighth transistor, and the third active connection part T31C is located at one side of the second active connection part T31B away from the integrated structure of the active layer T71 of the seventh transistor and the active layer T81 of the eighth transistor.

In an exemplary embodiment, as shown in FIG. 13, a straight line extending along the second direction passes through the first active connection part T31A and the active layer T21 of the second transistor.

In an exemplary embodiment, as shown in FIG. 13, a straight line extending along the second direction passes through the third active connection part T31C and the active layer T11 of the first transistor.

In an exemplary embodiment, as shown in FIG. 13, the active layer T51 of the fifth transistor is located at one side of the active layer T31 of the third transistor away from the integrated structure of the active layer T71 of the seventh transistor and the active layer T81 of the eighth transistor, and extends along the first direction. The active layer T51 of the fifth transistor may be in the shape of a square.

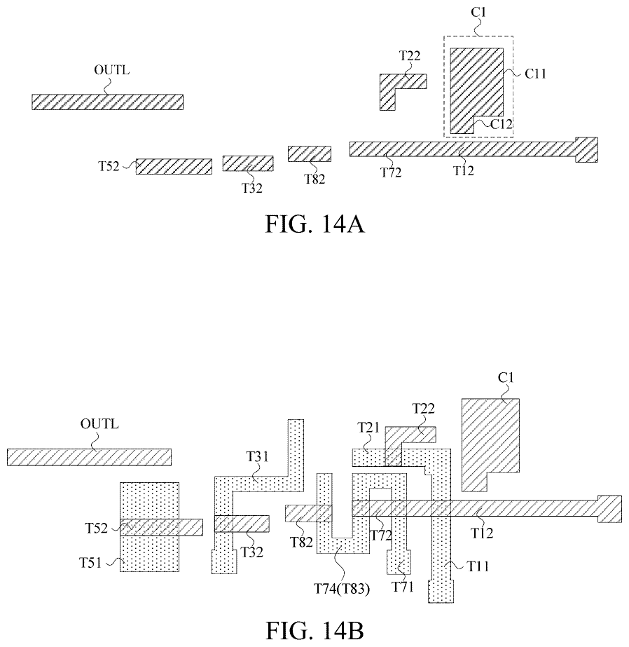

(2) Forming a pattern of a first conductive layer, which includes: depositing a first insulating film and a first conductive film on the substrate, on which the aforementioned patterns are formed, and patterning the first insulating film and the first conductive film through the patterning processes to form a pattern of a first insulating layer and a pattern of the first conductive layer disposed on the pattern of the first insulating layer, as shown in FIGS. 14A and 14B. FIG. 14A is a schematic diagram of the pattern of the first conductive layer, and FIG. 14B is a schematic diagram after a pattern of the first conductive layer is formed.

In an exemplary embodiment, as shown in FIGS. 14A and 14B, the pattern of the first conductive layer may include a control electrode T12 of the first transistor, a control electrode T22 of the second transistor, a control electrode T32 of the third transistor, a control electrode T52 of the fifth transistor, a control electrode T72 of the seventh transistor, a control electrode T82 of the eighth transistor, a first plate C1 of a capacitor C and a signal output line OUTL.

In an exemplary embodiment, the first conductive layer may be made of a metal material, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be a single-layered structure or a multi-layered composite structure, such as Ti/Al/Ti, etc.

In an exemplary embodiment, the first insulating layer may be made of any one or more of silicon oxide (SiOx), silicon nitride (SiNx) and silicon oxynitride (SiON), and may be a single-layer, multi-layers or a composite layer. The first insulating layer may be referred to as a first gate insulating layer.

In an exemplary embodiment, as shown in FIGS. 14A and 14B, the first plate C1 of the capacitor may include a first capacitor body part C11 and a first capacitor connection part C12 connected to each other. The first capacitor connection part C12 is located at one side of the first capacitor body part C11.

In an exemplary embodiment, as shown in FIGS. 14A and 14B, the area of the first capacitor connection part C12 is less than the area of the first capacitor body part C11.

In an exemplary embodiment, as shown in FIGS. 14A and 14B, the control electrode T12 of the first transistor and the control electrode T72 of the seventh transistor form an integral structure. The integrated structure of the control electrode T12 of the first transistor and the control electrode T72 of the seventh transistor extends along the second direction and may be strip-shaped.

In an exemplary embodiment, as shown in FIGS. 14A and 14B, the integrated structure of the control electrode T12 of the first transistor and the control electrode T72 of the seventh transistor may be located at one side of the first capacitor connection part C12 away from the first capacitor body part C11.

In an exemplary embodiment, as shown in FIGS. 14A and 14B, the control electrode T22 of the second transistor and the first plate C1 of the capacitor are located at the same side of the integrated structure of the control electrode T12 of the first transistor and the control electrode T72 of the seventh transistor, and the control electrode T22 of the second transistor is located at one side of the first plate C1 of the capacitor close to the signal output line. The control electrodes T22 of the second transistor may be in the shape of an L rotated by 90 degrees.

In an exemplary embodiment, as shown in FIGS. 14A and 14B, the control electrode T82 of the eighth transistor may be located at one side of the integrated structure of the control electrode T12 of the first transistor and the control electrode T72 of the seventh transistor, and a virtual straight line extending along the second direction passes through the control electrode T82 of the eighth transistor and the integrated structure of the control electrode T12 of the first transistor and the control electrode T72 of the seventh transistor.

In an exemplary embodiment, as shown in FIGS. 14A and 14B, the control electrode T82 of the eighth transistor extends along the second direction and may be strip-shaped.

In an exemplary embodiment, as shown in FIGS. 14A and 14B, the control electrode T32 of the third transistor may be located at one side of the control electrode T82 of the eighth transistor away from the integrated structure of the control electrode T12 of the first transistor and the control electrode T72 of the seventh transistor, and a virtual straight line extending along the second direction passes through the control electrode T32 of the third transistor and the control electrode T82 of the eighth transistor.

In an exemplary embodiment, as shown in FIGS. 14A and 14B, the control electrode T32 of the third transistor extends along the second direction and may be strip-shaped.

In an exemplary embodiment, as shown in FIGS. 14A and 14B, the control electrode T52 of the fifth transistor may be located at one side of the control electrode T32 of the third transistor away from the control electrode T82 of the eighth transistor, and a virtual straight line extending along the second direction passes through the control electrode T52 of the fifth transistor and the control electrode T32 of the third transistor.

In an exemplary embodiment, as shown in FIGS. 14A and 14B, the control electrode T52 of the fifth transistor extends along the second direction and may be strip-shaped.

In an exemplary embodiment, as shown in FIGS. 14A and 14B, the signal output line OUTL may be located at one side of the control electrode T22 of the second transistor away from the first plate C1 of the capacitor, and a virtual straight line extending along the second direction passes through the signal output line OUTL and the control electrode T22 of the second transistor.

In an exemplary embodiment, as shown in FIGS. 14A and 14B, the signal output line OUTL extends along the second direction and may be strip-shaped.

In an exemplary embodiment, as shown in FIGS. 14A and 14B, the control electrode T12 of the first transistor is arranged across the active layer of the first transistor, the control electrode T22 of the second transistor is arranged across the active layer of the second transistor, the control electrode T32 of the third transistor is arranged across the active layer of the third transistor, the control electrode T52 of the fifth transistor is arranged across the active layer of the fifth transistor, the control electrode T72 of the seventh transistor is arranged across the active layer of the seventh transistor, and the control electrode T82 of the eighth transistor is arranged across the active layer of the eighth transistor, that is, the extension direction of the control electrode of at least one transistor is perpendicular to the extension direction of its active layer.

In an exemplary embodiment, this running of the processes further includes a conductorization process. The conductorization process includes, after the first conductive layer is formed, using the semiconductor layer in an area blocked by control electrodes of a plurality of transistors (i.e., an area where the semiconductor layer overlaps with the control electrodes) as channel regions of the transistors, and the semiconductor layer which is not blocked by the first conductive layer is processed to become a conductorization layer to form electrode connection parts of the transistors. As shown in FIG. 14B, the interconnected electrode connection parts of the active layer T71 of the seventh transistor and the active layer T81 of the eighth transistor in the present disclosure are processed to become a conductorization layer to form a conductorization structure that can be reused as a second electrode of the seventh transistor and a first electrode of the eighth transistor.

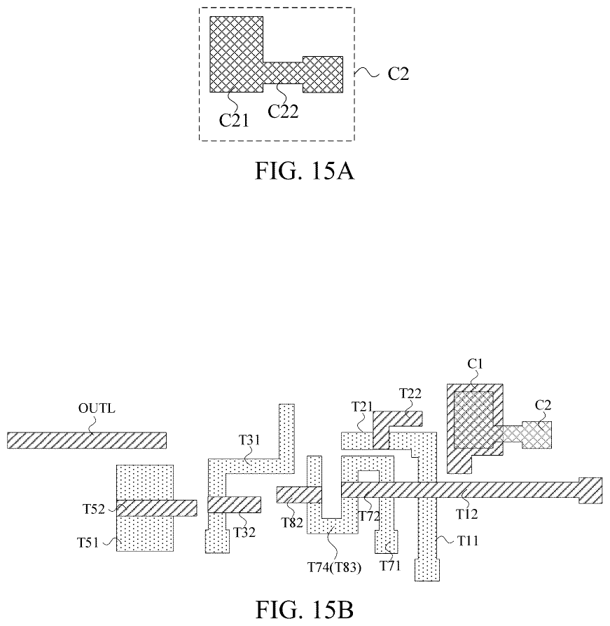

(3) Forming a pattern of a second conductive layer, which includes: depositing a second insulating film and a second conductive film on the substrate, on which the aforementioned patterns are formed, and patterning the second insulating film and the second conductive film through the patterning processes to form a pattern of a second insulating layer and a pattern of the second conductive layer located on the pattern of the second insulating layer, as shown in FIGS. 15A and 15B. FIG. 15A is a schematic diagram of the pattern of the second conductive layer, and FIG. 15B is a schematic diagram after a pattern of the second conductive layer is formed.

In an exemplary embodiment, as shown in FIGS. 15A and 15B, the pattern of the second conductive layer pattern may include a second plate C2 of the capacitor.

In an exemplary embodiment, the second conductive layer may be made of a metal material, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be a single-layered structure or a multi-layered composite structure, such as Ti/Al/Ti, etc.

In an exemplary embodiment, the second insulating layer may be made of any one or more of silicon oxide (SiOx), silicon nitride (SiNx) and silicon oxynitride (SiON), and may be a single-layer, multi-layers or a composite layer. The second insulating layer may be referred to as a second gate insulating layer.

In an exemplary embodiment, as shown in FIGS. 15A and 15B, the second plate C2 of the capacitor may include a second capacitor body part C21 and a second capacitor connection part C22 connected to each other. The second capacitor connection part C22 is located at one side of the second capacitor body part C21.

In an exemplary embodiment, as shown in FIGS. 15A and 15B, the second plate C2 of the capacitor may be L-shaped. The second capacitor body part C21 may be strip-shaped and extend along the second direction, and the second capacitor connection part C22 may be strip-shaped and extend along the first direction.

In an exemplary embodiment, as shown in FIGS. 15A and 15B, the area of the first capacitor body part C11 of the first plate of the capacitor is greater than the area of the second capacitor body part C21 of the second plate of the capacitor.

In an exemplary embodiment, as shown in FIGS. 15A and 15B, orthographic projections of the second capacitor body part C21 and the second capacitor connection part C22 on the substrate overlap at least partially with an orthographic projection of the first capacitor body part of the first plate of the capacitor on the substrate, and do not overlap with an orthographic projection of the first capacitor connection part of the first plate of the capacitor on the substrate.

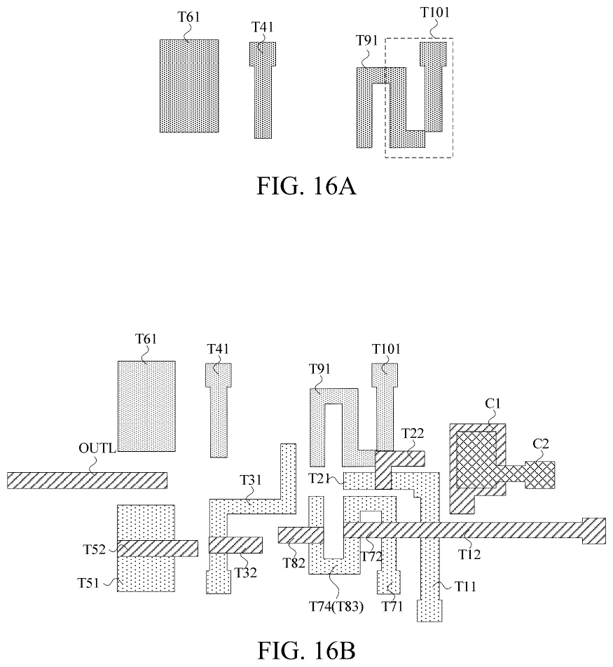

(4) Forming a pattern of a second semiconductor layer, which includes: depositing a third insulating film and a second semiconductor film on the substrate, on which the aforementioned patterns are formed, and patterning the third insulating film and the second semiconductor film through the patterning processes to form a pattern of a third insulating layer and a pattern of the second semiconductor layer disposed on the pattern of the third insulating layer, as shown in FIGS. 16A and 16B. FIG. 16A is a schematic diagram of the pattern of the second semiconductor layer, and FIG. 16B is a schematic diagram after a pattern of the second semiconductor layer is formed.

In an exemplary embodiment, as shown in FIGS. 16A and 16B, the pattern of the second semiconductor layer may include an active layer T41 of a fourth transistor, an active layer T61 of a sixth transistor, an active layer T91 of a ninth transistor and an active layer T101 of a tenth transistor.

In an exemplary embodiment, the second semiconductor layer may be a metal oxide layer. The metal oxide layer may be made of an oxide containing indium and tin, an oxide containing tungsten and indium, an oxide containing tungsten, indium and zinc, an oxide containing titanium and indium, an oxide containing titanium, indium and tin, an oxide containing indium and zinc, an oxide containing silicon, indium and tin or an oxide containing indium or gallium and zinc. The metal oxide layer may be a single layer, double layers or multi layers.

In an exemplary embodiment, the third insulating layer may be made of any one or more of silicon oxide (SiOx), silicon nitride (SiNx) and silicon oxynitride (SiON), and may be a single layer, multi-layers or a composite layer.

In an exemplary embodiment, as shown in FIGS. 16A and 16B, the active layer T91 of the ninth transistor and the active layer T101 of the tenth transistor may form an integrated structure.

In an exemplary embodiment, as shown in FIGS. 16A and 16B, the active layer T61 of the sixth transistor extends along the first direction and may be a strip-shaped structure. An orthographic projection of the active layer T61 of the sixth transistor on the substrate and an orthographic projection of the active layer T51 of the fifth transistor on the substrate are located at two opposite sides of an orthographic projection of the signal output line OUTL on the substrate respectively, and a straight line extending along the first direction passes through the active layer T51 of the fifth transistor and the active layer T61 of the sixth transistor.

In an exemplary embodiment, the orthographic projection of the active layer T51 of the fifth transistor on the substrate and the orthographic projection of the active layer T61 of the sixth transistor on the substrate may be arranged symmetrically about a virtual straight line extending along the second direction.

In an exemplary embodiment, as shown in FIGS. 16A and 16B, the active layer T41 of the fourth transistor extends along the first direction and may be a strip-shaped structure. A straight line extending along the first direction passes through the active layer T41 of the fourth transistor and the third active connection part of the active layer T31 of the third transistor.

In an exemplary embodiment, an orthographic projection of the active layer T41 of the fourth transistor on the substrate and an orthographic projection of the third active connection part of the active layer T31 of the third transistor on the substrate may be arranged symmetrically about a virtual straight line extending along the second direction.

In an exemplary embodiment, as shown in FIGS. 16A and 16B, the active layer T91 of the ninth transistor may be inverted L-shaped, and the active layers T101 of the tenth transistor may be n-shaped. A straight line extending along the first direction passes through the active layer T91 of the ninth transistor and the active layer T81 of the eighth transistor, and a straight line extending along the first direction passes through the active layer T101 of the tenth transistor and the active layer T71 of the seventh transistor.

In an exemplary embodiment, an orthographic projection of the active layer T91 of the ninth transistor on the substrate and an orthographic projection of the active layer T81 of the eighth transistor on the substrate may be arranged symmetrically about a virtual straight line extending along the second direction.

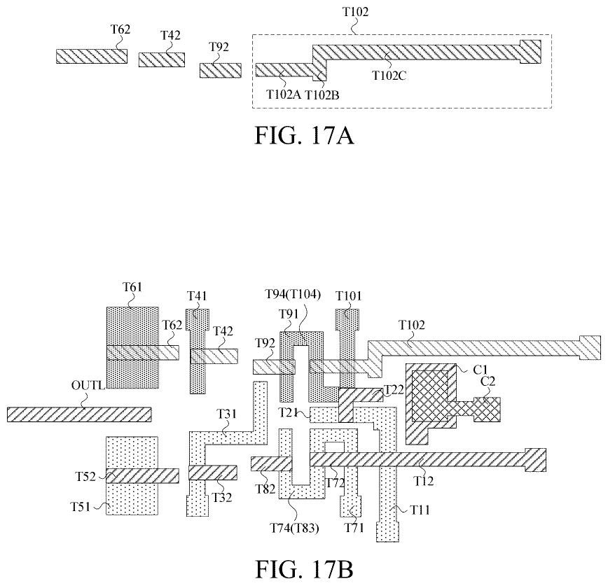

(5) forming a pattern of a third conductive layer, which includes: depositing a fourth insulating film and a third conductive film on the substrate, on which the aforementioned patterns are formed, and patterning the fourth insulating film and the third conductive film through the patterning processes to form a pattern of a fourth insulating layer and a pattern of the third conductive layer disposed on the pattern of the fourth insulating layer, as shown in FIG. 17A and FIG. 17B. FIG. 17A is a schematic diagram of the pattern of the third conductive layer, and FIG. 17B is a schematic diagram after a pattern of the third conductive layer is formed.

In an exemplary embodiment, as shown in FIGS. 17A and 17B, the pattern of the third conductive layer may include a control electrode T42 of the fourth transistor, a control electrode T62 of the sixth transistor, a control electrode T92 of the ninth transistor, and a control electrode T102 of the tenth transistor.

In an exemplary embodiment, the third conductive layer may be made of a metal material, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be a single-layered structure or a multi-layered composite structure, such as Ti/Al/Ti, etc.

In an exemplary embodiment, the fourth insulating layer may be made of any one or more of silicon oxide (SiOx), silicon nitride (SiNx) and silicon oxynitride (SiON), and may be a single-layer, multi-layers or a composite layer.

In an exemplary embodiment, as shown in FIGS. 17A and 17B, the control electrode T42 of the fourth transistor and the control electrode T62 of the sixth transistor extend along the second direction and may be strip-shaped. The control electrode T42 of the fourth transistor is located at one side of the control electrode T62 of the sixth transistor, and a virtual straight line extending along the second direction passes through the control electrode T42 of the fourth transistor and the control electrode T62 of the sixth transistor.

In an exemplary embodiment, as shown in FIGS. 17A and 17B, the control electrode T92 of the ninth transistor extends along the second direction and may be strip-shaped. The control electrode T92 of the ninth transistor may be located at one side of the control electrode T42 of the fourth transistor away from the control electrode T62 of the sixth transistor, and a virtual straight line extending along the second direction passes through the control electrode T42 of the fourth transistor and the control electrode T92 of the ninth transistor.

In an exemplary embodiment, as shown in FIGS. 17A and 17B, the control electrode T102 of the tenth transistor may be located at one side of the control electrode T92 of the ninth transistor away from the control electrode T42 of the fourth transistor.

In an exemplary embodiment, as shown in FIGS. 17A and 17B, the control electrode T102 of the tenth transistor may include a first electrode connection part T102A, a second electrode connection part T102B and a third electrode connection part T102C. The first electrode connection part T102A and the third electrode connection part T102C extend along the second direction, and the second electrode connection part T102B extends along the first direction and is connected to the first electrode connection part T102A and the third electrode connection part T102C, respectively.

In an exemplary embodiment, as shown in FIGS. 17A and 17B, the first electrode connection part T102A and the third electrode connection part T102C are located at two opposite sides of the second electrode connection part T102B respectively. The first electrode connection part T102A may be located at one side of the second electrode connection part T102B close to the control electrode T92 of the ninth transistor, and the third electrode connection part T102C may be located at one side of the second electrode connection part T102B away from the control electrode T92 of the ninth transistor.

In an exemplary embodiment, as shown in FIGS. 17A and 17B, a virtual straight line extending along the second direction passes through an orthographic projection of the first electrode connection part T102A of the control electrode T102 of the tenth transistor on the substrate and the orthographic projection of the first capacitor body part of the first plate of the capacitor on the substrate. An orthographic projection of the third electrode connection part T102C of the control electrode T102 of the tenth transistor on the substrate is located at one side of an orthographic projection of the first plate of the capacitor on the substrate away from an orthographic projection of the integrated structure of the control electrode of the first transistor and the control electrode of the seventh transistor on the substrate.

In an exemplary embodiment, as shown in FIGS. 17A and 17B, the control electrode T42 of the fourth transistor is arranged across the active layer T41 of the fourth transistor, the control electrode T62 of the sixth transistor is arranged across the active layer T61 of the sixth transistor, the control electrode T92 of the ninth transistor is arranged across the active layer T91 of the ninth transistor, and the control electrode T102 of the tenth transistor is arranged across the active layer T101 of the tenth transistor, that is, the extension direction of the control electrode at least one transistor is perpendicular to the extension direction of its active layer.

In an exemplary embodiment, this running of the processes further includes a conductorization process. The conductorization process includes, after the third conductive layer is formed, using a second semiconductor layer in an area blocked by control electrodes of a plurality of transistors (i.e., an area where the semiconductor layer overlaps with the control electrodes) as channel regions of the transistors, and the semiconductor layer which is not blocked by the third conductive layer is processed to become a conductorization layer to form electrode connection parts of the transistors. As shown in FIG. 17B, the interconnected electrode connection parts of the active layer T91 of the ninth transistor and the active layer T101 of the tenth transistor in the present disclosure are processed to become a conductorization layer to form a conductorization structure that can be reused as a second electrode of the ninth transistor and a second electrode of the tenth transistor.

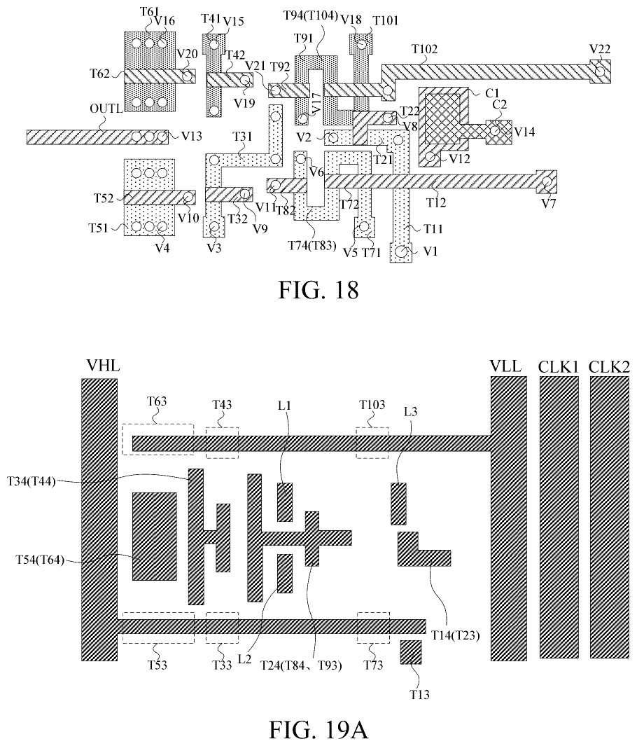

(6) Forming a pattern of a fifth insulating layer, which includes: depositing a fifth insulating film on the substrate, on which the aforementioned patterns are formed, and patterning the fifth insulating film through the patterning processes to form the pattern of the fifth insulating layer overlaying the aforementioned structure. A pattern of a plurality of via holes is provided in the fifth insulating layer, as shown in FIG. 18. FIG. 18 is a schematic diagram after a pattern of the fifth insulating layer is formed.

In an exemplary embodiment, as shown in FIG. 18, the pattern of the plurality of via holes may include a first via hole V1 through a sixth via hole V6 provided in the first insulating layer, the second insulating layer and the fifth insulating layer, a seventh via hole V7 through thirteenth via holes V13 provided in the second insulating layer through fifth insulating layer, a fourteenth via hole V14 provided in the third insulating layer through fifth insulating layer, a fifteenth via hole V15 through an eighteenth via hole V18 provided in the fourth insulating layer and fifth insulating layer, and a nineteenth via hole V19 through twenty-second via holes V22 provided in the fifth insulating layer.

In an exemplary embodiment, the fifth insulating layer may be made of any one or more of silicon oxide (SiOx), silicon nitride (SiNx) and silicon oxynitride (SiON), and may be a single-layer, multi-layers or a composite layer. The fifth insulating layer may be referred to as a second gate insulating layer.

As shown in FIG. 18, the first via hole VI exposes the active layer T11 of the first transistor, the second via hole V1 exposes the active layer T21 of the second transistor, the third via holes V3 expose the active layer T31 of the third transistor, the fourth via holes V4 expose the active layer T51 of the fifth transistor, the fifth via hole V5 exposes the active layer T71 of the seventh transistor, the sixth via hole V6 exposes the active layer T81 of the eighth transistor, the seventh via hole V7 exposes the integrated structure of the control electrode T12 of the first transistor and the control electrode T72 of the seventh transistor, the eighth via hole V8 exposes the control electrode T22 of the second transistor, the ninth via hole V9 exposes the control electrode T32 of the third transistor, the tenth via hole V10 exposes the control electrode T52 of the fifth transistor, the eleventh via hole V11 exposes the control electrode T82 of the eighth transistor, the twelfth via hole V12 exposes the first plate C1 of the capacitor, the thirteenth via holes V13 expose the signal output line OUTL, the fourteenth via hole V14 exposes the second plate C2 of the capacitor, the fifteenth via hole V15 exposes the active layer T41 of the fourth transistor, the sixteenth via holes V16 expose the active layer T61 of the sixth transistor, the seventeenth via hole V17 exposes the active layer T91 of the ninth transistor, the eighteenth via hole V18 exposes the active layer T101 of the tenth transistor, the nineteenth via hole V19 exposes the control electrode T42 of the fourth transistor, the twentieth via hole V20 exposes the control electrode T62 of the sixth transistor, the twenty-first via hole V21 exposes the control electrode T92 of the ninth transistor, and the twenty-second via holes V22 expose the control electrode T102 of the tenth transistor.

In an exemplary embodiment, as shown in FIG. 18, the number of the third via holes V3 is four, a virtual straight line extending along the first direction passes through the first one of the third via holes and the second one of the third via holes, and the first one of the third via holes and the second one of the third via holes expose the first active connection part of the active layer T31 of the third transistor, a virtual straight line extending along the first direction passes through the third one of the third via holes and the fourth one of the third via holes, the third one of the third via holes and the fourth one of the third via hole expose the third active connection part of the active layer T31 of the third transistor, and a virtual straight line extending along the second direction passes through the second one of the third via holes and the third one of the third via holes.

In an exemplary embodiment, as shown in FIG. 18, the number of the fourth via holes V4 is plural, and the plurality of fourth via holes V4 is arranged in an array.

In an exemplary embodiment, as shown in FIG. 18, the number of the thirteenth via holes V13 may be plural, and the plurality of thirteenth via holes V13 is arranged along the second direction.

In an exemplary embodiment, as shown in FIG. 18, the number of the sixteenth via holes V16 is plural, and the plurality of sixteenth via holes V16 is arranged in an array.

In an exemplary embodiment, as shown in FIG. 18, the number of the twenty-second via holes V22 may be two. The first one of the twenty-second via holes exposes the second electrode connection part of the control electrode T102 of the tenth transistor, and the second one of the twenty-second via holes exposes the third electrode connection part of the control electrode T102 of the tenth transistor.

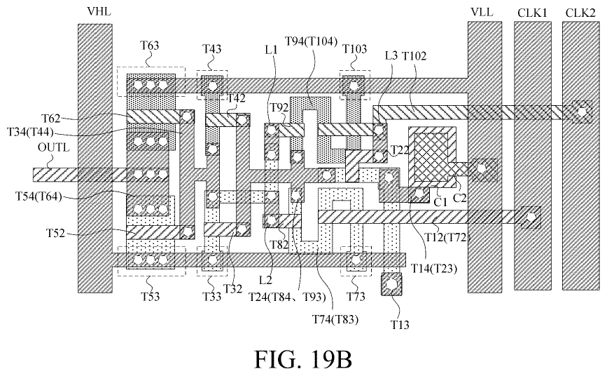

(7) Forming a pattern of a fourth conductive layer, which includes: depositing a fourth metal film on the substrate, on which the aforementioned patterns are formed, and patterning the fourth metal film through the patterning processes to form the pattern of the fourth metal layer, as shown in FIGS. 19A and 19B. FIG. 19A is a schematic diagram of the pattern of the fourth conductive layer, and FIG. 19B is a schematic diagram after a pattern of the fourth conductive layer is formed.

In an exemplary embodiment, as shown in FIGS. 19A and 19B, the pattern of the fourth conductive layer may include a first clock signal line CLK1, a second clock signal line CLK2, a first power supply line VHL, a second power supply line VLL, a first electrode T13 and a second electrode T14 of the first transistor to a first electrode T63 and a second electrode T64 of the sixth transistor, a first electrode T73 of the seventh transistor, a second electrode T84 of the eighth transistor, a first electrode T93 of the ninth transistor, a first electrode T103 of the tenth transistor, a first connection signal line L1, a second connection signal line L2 and a third connection signal line L3.

In an exemplary embodiment, the forth conductive film may be made of a metal material, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be a single-layered structure or a multi-layered composite structure, such as Ti/Al/Ti, etc.

In an exemplary embodiment, as shown in FIGS. 19A and 19B, the first electrode T33 of the third transistor, the first electrode T53 of the fifth transistor, the first electrode T73 of the seventh transistor and the first power supply line VHL form an integrated structure, the first electrode T43 of the fourth transistor, the first electrode T63 of the sixth transistor, the first electrode T103 of the tenth transistor and the second power supply line VLL form an integrated structure, the second electrode T14 of the first transistor and the first electrode T23 of the second transistor form an integrated structure, the second electrode T34 of the third transistor and the second electrode T44 of the fourth transistor form an integrated structure, the second electrode T24 of the second transistor, the second electrode T84 of the eighth transistor and the first electrode T93 of the ninth transistor form an integrated structure, and the second electrode T54 of the fifth transistor and the second electrode T64 of the sixth transistor form an integrated structure.

In an exemplary embodiment, as shown in FIGS. 19A and 19B, the first power supply line VHL is located at one side of the integrated structure of the second electrode T54 of the fifth transistor and the second electrode T64 of the sixth transistor away from the second power supply line VLL, the second power supply line VLL is located at one side of the integrated structure of the second electrode T14 of the first transistor and the first electrode T23 of the second transistor away from the first power supply line VHL, the first clock signal line CLK1 is located at one side of the second power supply line VHL away from the first power supply line VHL, and the second clock signal line CLK2 is located at one side of the first clock signal line CLK1 away from the second power supply line VLL.

In an exemplary embodiment, as shown in FIGS. 19A and 19B, the first power supply line VHL extends along the first direction and may be strip-shaped. An orthographic projection of the first power supply line VHL on the substrate overlaps at least partially with the orthographic projection of the signal output line OUTL on the substrate.

In an exemplary embodiment, as shown in FIGS. 19A and 19B, the first electrode T33 of the third transistor, the first electrode T53 of the fifth transistor and the first electrode T73 of the seventh transistor extend along the second direction and are located at one side of the first power supply line VHL close to the second power supply line VLL.

In an exemplary embodiment, as shown in FIGS. 19A and 19B, the second power supply line VLL extends along the first direction and may be strip-shaped. An orthographic projection of the second power supply line VLL on the substrate overlaps partially with orthographic projections of the integrated structure of the control electrode T12 of the first transistor and the control electrode T72 of the seventh transistor, the control electrode of the tenth transistor and the second capacitor connection part of the second plate C2 of the capacitor on the substrate.

In an exemplary embodiment, as shown in FIGS. 19A and 19B, the first electrode T43 of the fourth transistor, the first electrode T63 of the sixth transistor and the first electrode T103 of the tenth transistor extend along the second direction and are located at one side of the second power supply line VLL close to the first power supply line VHL.

In an exemplary embodiment, as shown in FIGS. 19A and 19B, the first clock signal line CLK1 extends along the first direction and may be strip-shaped. An orthographic projection of the first clock signal line CLK1 on the substrate overlaps partially with orthographic projections of the control electrode T102 of the tenth transistor and the integrated structure of the control electrode T12 of the first transistor and the control electrode T72 of the seventh transistor on the substrate.

In an exemplary embodiment, as shown in FIGS. 19A and 19B, the second clock signal line CLK2 extends along the first direction and may be strip-shaped. An orthographic projection of the second clock signal line CLK2 on the substrate overlaps partially with an orthographic projection of the control electrode T102 of the tenth transistor or an orthographic projection of the integrated structure of the control electrode T12 of the first transistor and the control electrode T72 of the seventh transistor on the substrate. When a second clock signal terminal of the shift register is electrically connected to the second clock signal line, the orthographic projection of the second clock signal line CLK2 on the substrate overlaps partially with the orthographic projection of the control electrode T102 of the tenth transistor on the substrate; when a first clock signal terminal of the shift register is electrically connected to the second clock signal line, the orthographic projection of the second clock signal line CLK2 on the substrate overlaps partially with the orthographic projection of the integrated structure of the control electrode T12 of the first transistor and the control electrode T72 of the seventh transistor on the substrate. FIGS. 19A and 19B are described by taking the orthographic projection of the second clock signal line CLK2 on the substrate overlapping partially with the orthographic projection of the control electrode T102 of the tenth transistor on the substrate as an example.

In an exemplary embodiment, as shown in FIGS. 19A and 19B, the integrated structure of the second electrode T14 of the first transistor and the first electrode T23 of the second transistor may be L-shaped, and an orthographic projection of the integrated structure of the second electrode T14 of the first transistor and the first electrode T23 of the second transistor on the substrate overlaps partially with the orthographic projection of the first capacitor connection part of the first plate of the capacitor on the substrate.

In an exemplary embodiment, as shown in FIGS. 19A and 19B, the integrated structure of the second electrode T34 of the third transistor and the second electrode T44 of the fourth transistor may be in the shape of the Chinese character “ [symbol] ” rotated by 90 degrees, and an orthographic projection of the integrated structure of the second electrode T34 of the third transistor and the second electrode T44 of the fourth transistor on the substrate overlaps partially with orthographic projections of the control electrode T62 of the sixth transistor and the control electrode T52 of the fifth transistor on the substrate.

In an exemplary embodiment, as shown in FIGS. 19A and 19B, the integrated structure of the second electrode T54 of the fifth transistor and the second electrode T64 of the sixth transistor extends along the first direction and may be strip-shaped. An orthographic projection of the integrated structure of the second electrode T54 of the fifth transistor and the second electrode T64 of the sixth transistor on the substrate overlaps partially with the orthographic projection of the signal output line OUTL on the substrate.

In an exemplary embodiment, as shown in FIGS. 19A and 19B, the integrated structure of the second electrode T24 of the second transistor, the second electrode T84 of the eighth transistor and the first electrode T93 of the ninth transistor may be in the shape of the Chinese character “ [symbol] ” rotated by 90 degrees, and an orthographic projection of the integrated structure of the second electrode T24 of the second transistor, the second electrode T84 of the eighth transistor and the first electrode T93 of the ninth transistor on the substrate overlaps partially with orthographic projections of the control electrode T32 of the third transistor and the control electrode T42 of the fourth transistor on the substrate.

In an exemplary embodiment, as shown in FIGS. 19A and 19B, the first connection signal line L1 extends along the first direction and may be strip-shaped. An orthographic projection of the first connection signal line L1 on the substrate overlaps partially with an orthographic projection of the control electrode T92 of the ninth transistor on the substrate.

In an exemplary embodiment, as shown in FIGS. 19A and 19B, the second connection signal line L2 extends along the first direction and may be strip-shaped. An orthographic projection of the second connection signal line L2 on the substrate overlaps partially with an orthographic projection of the control electrode T82 of the eighth transistor on the substrate.

In an exemplary embodiment, as shown in FIGS. 19A and 19B, the third connection signal line L3 extends along the first direction and may be strip-shaped. An orthographic projection of the third connection signal line L3 on the substrate overlaps partially with orthographic projections of the control electrode T22 of the second transistor and the control electrode T102 of the tenth transistor on the substrate.

In an exemplary embodiment, as shown in FIGS. 19A and 19B, the first electrode T13 and the second electrode T14 of the first transistor are connected to the active layer of the first transistor through the first via hole, the first electrode T23 of the second transistor and the second electrode T24 of the second transistor are connected to the active layer of the second transistor through the second via hole, the first electrode T33 and the second electrode T34 of the third transistor are connected to the active layer of the third transistor through the third one of the third via holes and the fourth one of the third via holes respectively, the first electrode T43 and the second electrode T44 of the fourth transistor are connected to the exposed active layer of the fourth transistor through the fifteenth via hole, the first electrode T53 and the second electrode T55 of the fifth transistor are connected to the active layer of the fifth transistor through the fourth via holes, the first electrode T63 and the second electrode T65 of the sixth transistor are connected to the active layer of the sixth transistor through the sixteenth via hole, the first electrode T73 of the seventh transistor is connected to the active layer of the seventh transistor through the fifth via hole, the second electrode T84 of the eighth transistor is connected to the active layer of the eighth transistor through the sixth via hole, the first electrode T93 of the ninth transistor is connected to the active layer of the ninth transistor through the seventeenth via hole, and the first electrode T103 of the tenth transistor is connected to the active layer of the tenth transistor through the eighteenth via hole. The integrated structure of the second electrode T14 of the first transistor and the first electrode T23 of the second transistor is connected to the first plate C1 of the capacitor through the twelfth via hole. The integrated structure of the second electrode T34 of the third transistor and the second electrode T44 of the fourth transistor is connected to the control electrode T62 of the sixth transistor through the twentieth via hole and is connected to the control electrode T52 of the fifth transistor through the tenth via hole. The integrated structure of the second electrode T24 of the second transistor, the second electrode T84 of the eighth transistor and the first electrode T93 of the ninth transistor is connected to the control electrode T42 of the fourth transistor through the nineteenth via hole and is connected to the control electrode T32 of the third transistor through the ninth via hole. The integrated structure of the second electrode T54 of the fifth transistor and the second electrode T64 of the sixth transistor is connected to the signal output line OUTL through the thirteenth via holes. The first connection signal line L1 is connected to the active layer of the third transistor through the first one of the third via holes and is connected to the control electrode T92 of the ninth transistor through the twenty-first via hole. The second connection signal line L2 is connected to the active layer of the third transistor through the second one of the third via holes and is connected to the control electrode T82 of the eighth transistor through the eleventh via hole. The third connection signal line L3 is connected to the control electrode T102 of the tenth transistor through the first one of the twenty-second via holes and is connected to the control electrode T22 of the second transistor through the eighth via hole. One of the first clock signal line CLK1 and the second clock signal line CLK2 is connected to the integrated structure of the control electrode T12 of the first transistor and the control electrode T72 of the seventh transistor through the seventh via hole. The other one of the first clock signal line CLK1 and the second clock signal line CLK2 is connected to the control electrode T102 of the tenth transistor through the second one of the twenty-second via holes. The second power supply line VLL is connected to the second plate C2 of the capacitor through the fourteenth via hole.

In an exemplary embodiment, as shown in FIGS. 19A and 19B, the control electrode T92 of the ninth transistor is connected to the integrated structure of the second electrode of the third transistor and the second electrode of the fourth transistor through the first connection signal line L1 and the active layer of the third transistor.

In an exemplary embodiment, as shown in FIGS. 19A and 19B, the control electrode T82 of the eighth transistor is connected to the integrated structure of the second electrode of the third transistor and the second electrode of the fourth transistor through the second connection signal line L2 and the active layer of the third transistor.

The embodiment of the present disclosure further provides a display device, which may include a display substrate.

The display substrate is the display substrate in accordance with any one of the foregoing embodiments, and its implementation principle and implementation effect are similar to the foresaid implementation principle and implementation effect and will not be repeated herein.

In an exemplary embodiment, the display device may be a liquid crystal display (LCD) or an organic light emitting diode (OLED) display device. The display device may be any product or component with a display function, such as a liquid crystal panel, electronic paper, an OLED panel, an active-matrix organic light emitting diode (AMOLED) panel, a mobile phone, a tablet computer, a television, a display, a notebook computer, a digital photo frame or a navigator.

The embodiment of the present disclosure further provides a driving method for a shift register, which is used for driving the shift register. The method includes the following steps.

In step 100, a storage sub-circuit stores a voltage difference between a signal of a first node and a signal of a first power supply terminal.

In step 200, a node control sub-circuit provides a signal of a signal input terminal to the first node under the control of a first clock signal terminal, and provides the signal of the first node to a second node under the control of a second clock signal terminal.

In step 300, an output control sub-circuit provides the signal of the first power supply terminal or a signal of a second power supply terminal to a signal output terminal under the control of the second node.

The shift register is the shift register in accordance with any one of the foregoing embodiments, and its implementation principle and implementation effect are similar to the foresaid implementation principle and implementation effect and will not be repeated herein.

The drawings in the embodiments of the present disclosure relate only to the structures involved in the embodiments of the present disclosure, and other structures may be described with reference to conventional designs.

For the sake of clarity, the thickness and size of a layer or a micro structure is enlarged in the drawings used to describe the embodiments of the present disclosure. It can be understood that when an element such as a layer, film, region or substrate is described as being “on” or “under” another element, this element may be “directly” located “on” or “under” the other element, or an intermediate element may exist.

Although the embodiments disclosed in the present disclosure are described as above, the described contents are only embodiments which are adopted in order to facilitate understanding of the present invention, and are not intended to limit the present disclosure. Any skilled person in the art to which the present invention pertains can make any modifications and alterations in forms and details of implementation without departing from the spirit and scope of the present invention. However, the patent protection scope of the present invention should be subject to the scope defined by the appended claims.

1. A shift register, comprising a storage sub-circuit, a node control sub-circuit and an output control sub-circuit, wherein:
the storage sub-circuit, electrically connected to a first node and a first power supply terminal respectively, is configured to store a voltage difference between a signal of the first node and a signal of the first power supply terminal;
the node control sub-circuit, electrically connected to a signal input terminal, a first clock signal terminal, a second clock signal terminal, the first node and a second node respectively, is configured to provide a signal of the signal input terminal to the first node under control of the first clock signal terminal and provide the signal of the first node to the second node under control of the second clock signal terminal; and
the output control sub-circuit, electrically connected to the second node, the first power supply terminal, a second power supply terminal and a signal output terminal respectively, is configured to provide the signal of the first power supply terminal or a signal of the second power supply terminal to the signal output terminal under control of the second node.

2. The shift register according to claim 1, wherein the output control sub-circuit comprises a first output control sub-circuit and a second output control sub-circuit, wherein
the first output control sub-circuit, electrically connected to the second node, a third node, the first power supply terminal and the second power supply terminal respectively, is configured to provide the signal of the first power supply terminal or the signal of the second power supply terminal to the third node under control of the second node; and
the second output control sub-circuit, electrically connected to the third node, the first power supply terminal, the second power supply terminal and the signal output terminal respectively, is configured to provide the signal of the first power supply terminal or the signal of the second power supply terminal to the signal output terminal under control of the third node.

3. The shift register according to claim 2, further comprising a noise reduction sub-circuit, wherein
the noise reduction sub-circuit, electrically connected to the first clock signal terminal, the second clock signal terminal, the first power supply terminal, the second power supply terminal, the second node and the third node respectively, is configured to provide the signal of the first power supply terminal or the signal of the second power supply terminal to the second node under control of the first clock signal terminal, the second clock signal terminal and the third node.

4. The shift register according to claim 1, wherein the storage sub-circuit comprises a capacitor comprising a first plate and a second plate, wherein
the first plate of the capacitor is electrically connected to the first node, and the second plate of the capacitor is electrically connected to the first power supply terminal.

5. The shift register according to claim 1, wherein the node control sub-circuit comprises a first transistor and a second transistor, wherein
a control electrode of the first transistor is electrically connected to the first clock signal terminal, a first electrode of the first transistor is electrically connected to the signal input terminal, and a second electrode of the first transistor is electrically connected to the first node; and
a control electrode of the second transistor is electrically connected to the second clock signal terminal, a first electrode of the second transistor is electrically connected to the first node, and a second electrode of the second transistor is electrically connected to the second node.

6. The shift register according to claim 2, wherein the first output control sub-circuit comprises a third transistor and a fourth transistor, and the second output control sub-circuit comprises a fifth transistor and a sixth transistor, wherein
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal; and
the third transistor and the fourth transistor are of opposite types, and the fifth transistor and the sixth transistor are of opposite types.

7. The shift register according to claim 3, wherein the noise reduction sub-circuit comprises a seventh transistor, an eighth transistor, a ninth transistor and a tenth transistor, wherein
a control electrode of the seventh transistor is electrically connected to the first clock signal terminal, a first electrode of the seventh transistor is electrically connected to the first power supply terminal, and a second electrode of the seventh transistor is electrically connected to a first electrode of the eighth transistor;
a control electrode of the eighth transistor is electrically connected to the third node, and a second electrode of the eighth transistor is electrically connected to the second node;
a control electrode of the ninth transistor is electrically connected to the third node, a first electrode of the ninth transistor is electrically connected to the second node, and a second electrode of the ninth transistor is electrically connected to a second electrode of the tenth transistor;
a control electrode of the tenth transistor is electrically connected to the second clock signal terminal, and a first electrode of the tenth transistor is electrically connected to the second power supply terminal; and
the seventh transistor and the eighth transistor are of a same type, the ninth transistor and the tenth transistor are of a same type, and the seventh transistor and the ninth transistor are of opposite types.

8. The shift register according to claim 1, wherein the storage sub-circuit comprises a capacitor comprising a first plate and a second plate; the node control sub-circuit comprises a first transistor and a second transistor; and the output control sub-circuit comprises a third transistor, a fourth transistor, a fifth transistor and a sixth transistor, wherein
the first plate of the capacitor is electrically connected to the first node, and the second plate of the capacitor is electrically connected to the first power supply terminal;
a control electrode of the first transistor is electrically connected to the first clock signal terminal, a first electrode of the first transistor is electrically connected to the signal input terminal, and a second electrode of the first transistor is electrically connected to the first node;
a control electrode of the second transistor is electrically connected to the second clock signal terminal, a first electrode of the second transistor is electrically connected to the first node, and a second electrode of the second transistor is electrically connected to the second node;
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal; and
the first transistor, the second transistor, the third transistor and the fifth transistor are P-type transistors, and the fourth transistor and the sixth transistor are N-type transistors and are oxide transistors.

9. The shift register according to claim 1, further comprising a noise reduction sub-circuit; wherein the storage sub-circuit comprises a capacitor comprising a first plate and a second plate; the node control sub-circuit comprises a first transistor and a second transistor; the output control sub-circuit comprises a third transistor, a fourth transistor, a fifth transistor and a sixth transistor; the noise reduction sub-circuit comprises a seventh transistor, an eighth transistor, a ninth transistor and a tenth transistor, wherein
the first plate of the capacitor is electrically connected to the first node, and the second plate of the capacitor is electrically connected to the first power supply terminal;
a control electrode of the first transistor is electrically connected to the first clock signal terminal, a first electrode of the first transistor is electrically connected to the signal input terminal, and a second electrode of the first transistor is electrically connected to the first node;
a control electrode of the second transistor is electrically connected to the second clock signal terminal, a first electrode of the second transistor is electrically connected to the first node, and a second electrode of the second transistor is electrically connected to the second node;
a control electrode of the third transistor is electrically connected to the second node, a first electrode of the third transistor is electrically connected to the first power supply terminal, and a second electrode of the third transistor is electrically connected to the third node;
a control electrode of the fourth transistor is electrically connected to the second node, a first electrode of the fourth transistor is electrically connected to the second power supply terminal, and a second electrode of the fourth transistor is electrically connected to the third node;
a control electrode of the fifth transistor is electrically connected to the third node, a first electrode of the fifth transistor is electrically connected to the first power supply terminal, and a second electrode of the fifth transistor is electrically connected to the signal output terminal;
a control electrode of the sixth transistor is electrically connected to the third node, a first electrode of the sixth transistor is electrically connected to the second power supply terminal, and a second electrode of the sixth transistor is electrically connected to the signal output terminal;
a control electrode of the seventh transistor is electrically connected to the first clock signal terminal, a first electrode of the seventh transistor is electrically connected to the first power supply terminal, and a second electrode of the seventh transistor is electrically connected to a first electrode of the eighth transistor;
a control electrode of the eighth transistor is electrically connected to the third node, and a second electrode of the eighth transistor is electrically connected to the second node;
a control electrode of the ninth transistor is electrically connected to the third node, a first electrode of the ninth transistor is electrically connected to the second node, and a second electrode of the ninth transistor is electrically connected to a second electrode of the tenth transistor;
a control electrode of the tenth transistor is electrically connected to the second clock signal terminal, and a first electrode of the tenth transistor is electrically connected to the second power supply terminal; and
the first transistor, the second transistor, the third transistor, the fifth transistor, the seventh transistor and the eighth transistor are P-type transistors, and the fourth transistor, the sixth transistor, the ninth transistor and the tenth transistor are N-type transistors and are oxide transistors.

10. The shift register according to claim 1, wherein a clock signal of the first clock signal terminal and a clock signal of the second clock signal terminal are inverted signals with respect to each other;
the signal of the signal input terminal is a first pulse signal, a duration of the first pulse signal is equal to a period of the clock signal of the first clock signal terminal; and
a signal of the signal output terminal is a second pulse signal, a duration of the second pulse signal is equal to the duration of the first pulse signal, and start time of the second pulse signal is end time of the first pulse signal.

11. The shift register according to claim 1, wherein a clock signal of the first clock signal terminal and a clock signal of the second clock signal terminal are inverted signals with respect to each other;
the signal of the signal input terminal is a third pulse signal, a duration of the third pulse signal is equal to N times a period of the clock signal of the first clock signal terminal, N being a positive integer greater than or equal to 2; and
a signal of the signal output terminal is a fourth pulse signal, a duration of the fourth pulse signal is equal to the duration of the third pulse signal, and a difference between start time of the fourth pulse signal and start time of the third pulse signal is equal to the period of the clock signal of the first clock signal terminal.

12. A display substrate, comprising a display area and a non-display area, wherein:
the display substrate comprises a substrate and a circuit structure layer disposed on the substrate, the circuit structure layer comprises a gate driving circuit located in the non-display area and pixel circuits arranged in an array located in the display area, the gate driving circuit comprises a plurality of cascaded shift registers, each shift register of the plurality of cascaded shift registers comprises a storage sub-circuit, a node control sub-circuit and an output control sub-circuit,
the storage sub-circuit, electrically connected to a first node and a first power supply terminal respectively, is configured to store a voltage difference between a signal of the first node and a signal of the first power supply terminal;
the node control sub-circuit, electrically connected to a signal input terminal, a first clock signal terminal, a second clock signal terminal, the first node and a second node respectively, is configured to provide a signal of the signal input terminal to the first node under control of the first clock signal terminal and provide the signal of the first node to the second node under control of the second clock signal terminal;
the output control sub-circuit, electrically connected to the second node, the first power supply terminal, a second power supply terminal and a signal output terminal respectively, is configured to provide the signal of the first power supply terminal or a signal of the second power supply terminal to the signal output terminal under control of the second node;
the pixel circuits are connected with a light emitting signal line, a scan signal line and a reset signal line;
a signal output terminal of an i-th stage shift register is electrically connected to a signal input terminal of an (i+1)-th stage shift register, 1≤i≤M−1, and M being the total number of stages of the shift registers; and
the gate driving circuit is electrically connected to at least one of the light emitting signal line, the scan signal line and the reset signal line.

13. The display substrate according to claim 12, further comprising a first clock signal line, a second clock signal line, a first power supply line and a second power supply line extending along a first direction, wherein
the first power supply line, the second power supply line, the first clock signal line and the second clock signal line being arranged along a second direction, and the first direction is intersected with the second direction;
first power supply terminals of all the shift registers are electrically connected to the first power supply line, second power supply terminals of all the shift registers are electrically connected to the second power supply line, a first clock signal terminal of the i-th stage shift register is electrically connected to the first clock signal line, a second clock signal terminal of the i-th stage shift register is electrically connected to the second clock signal line, a first clock signal terminal of the (i+1)-th stage shift register is electrically connected to the second clock signal line, and a second clock signal terminal of the (i+1)-th stage shift register is electrically connected to the first clock signal line.

14. The display substrate according to claim 13, wherein each of the shift registers comprises a first transistor through a tenth transistor and a capacitor, the capacitor comprises a first plate and second plate, and the circuit structure layer comprises a first semiconductor layer, a first insulating layer, a first conductive layer, a second insulating layer, a second conductive layer, a third insulating layer, a second semiconductor layer, a fourth insulating layer, a third conductive layer, a fifth insulating layer and a fourth conductive layer which are sequentially stacked on the substrate, wherein
the first semiconductor layer comprises an active layer of the first transistor, an active layer of the second transistor, an active layer of the third transistor, an active layer of the fifth transistor, an active layer of the seventh transistor and an active layer of the eighth transistor;
the first conductive layer comprises a control electrode of the first transistor, a control electrode of the second transistor, a control electrode of the third transistor, a control electrode of the fifth transistor, a control electrode of the seventh transistor, a control electrode of the eighth transistor, the first plate of the capacitor and a signal output line;
the second conductive layer comprises the second plate of the capacitor;
the second semiconductor layer comprises an active layer of the fourth transistor, an active layer of the sixth transistor, an active layer of the ninth transistor and an active layer of the tenth transistor;
the third conductive layer comprises a control electrode of the fourth transistor, a control electrode of the sixth transistor, a control electrode of the ninth transistor and a control electrode of the tenth transistor;
the fourth conductive layer comprises the first clock signal line, the second clock signal line, the first power supply line, the second power supply line, first electrodes and second electrodes of the first transistor through the sixth transistor, a first electrode of the seventh transistor, a second electrode of the eighth transistor, a first electrode of the ninth transistor, a first electrode of the tenth transistor, a first connection signal line, a second connection signal line and a third connection signal line;
the signal output line is connected to the second electrode of the fifth transistor and the second electrode of the sixth transistor respectively;
the first connection signal line is connected to the active layer of the third transistor and the control electrode of the ninth transistor respectively;
the second connection signal line is connected to the active layer of the third transistor and the control electrode of the eighth transistor respectively; and
the third connection signal line is connected to the control electrode of the tenth transistor and the control electrode of the second transistor respectively.

15. The display substrate according to claim 14, wherein the fifth transistor and the sixth transistor are located at a same side of the first power supply line, and the fifth transistor and the sixth transistor are arranged along the first direction;
the third transistor is located at a side of the fifth transistor away from the first power supply line, the fourth transistor is located at a side of the sixth transistor away from the first power supply line, the third transistor and the fourth transistor are arranged along the first direction, the third transistor and the fifth transistor are arranged along the second direction, and the fourth transistor and the sixth transistor are arranged along the second direction;
the eighth transistor is located at a side of the third transistor away from the fifth transistor, the ninth transistor is located at a side of the fourth transistor away from the sixth transistor, the eighth transistor and the ninth transistor are arranged along the first direction, the third transistor and the eighth transistor are arranged along the second direction, and the fourth transistor and the ninth transistor are arranged along the second direction;
the seventh transistor is located at a side of the eighth transistor away from the third transistor, the tenth transistor is located at a side of the ninth transistor away from the fourth transistor, the seventh transistor and the tenth transistor are arranged along the first direction, the seventh transistor and the eighth transistor are arranged along the second direction, and the ninth transistor and the tenth transistor are arranged along the second direction;
the second transistor is located between the seventh transistor and the tenth transistor, the first transistor is located at a side of the seventh transistor away from the eighth transistor, and the capacitor is located at a side of the tenth transistor away from the ninth transistor; and
the second power supply line is located at a side of the capacitor away from the tenth transistor, the first clock signal line is located at a side of the second power supply line away from the capacitor, and the second clock signal line is located at a side of the first clock signal line away from the second power supply line.

16. The display substrate according to claim 14, wherein the active layer of the first transistor and the active layer of the second transistor form an integrated structure, and the active layer of the seventh transistor and the active layer of the eighth transistor form an integrated structure;
the active layer of the third transistor comprises a first active connection part, a second active connection part and a third active connection part, wherein the first active connection part and the third active connection part are extended along the first direction, and the second active connection part is extended along the second direction and is connected to the first active connection part and the third active connection part respectively;
the first active connection part is located at a side of the second active connection part close to the integrated structure of the active layer of the seventh transistor and the active layer of the eighth transistor, and the third active connection part is located at a side of the second active connection part away from the integrated structure of the active layer of the seventh transistor and the active layer of the eighth transistor;
a straight line extending along the second direction passes through the first active connection part and the active layer of the second transistor; and
a straight line extending along the second direction passes through the third active connection part and the active layer of the first transistor.

17. The display substrate according to claim 16, wherein the first plate of the capacitor comprises a first capacitor body part and a first capacitor connection part connected to each other;
the control electrode of the first transistor and the control electrode of the seventh transistor form an integrated structure, and are located at a side of the first capacitor connection part away from the first capacitor body part;
a virtual straight line extending along the second direction passes through the control electrode of the eighth transistor and the integrated structure of the control electrode of the first transistor and the control electrode of the seventh transistor;
a virtual straight line extending along the second direction passes through the control electrode of the third transistor and the control electrode of the eighth transistor;
a virtual straight line extending along the second direction passes through the control electrode of the fifth transistor and the control electrode of the third transistor; and
a virtual straight line extending along the second direction passes through the signal output line and the control electrode of the second transistor.

18. The display substrate according to claim 17, wherein the second plate of the capacitor comprises a second capacitor body part and a second capacitor connection part connected to each other, wherein the second capacitor connection part is located at a side of the second capacitor body part;
an area of the first capacitor body part of the first plate of the capacitor is greater than an area of the second capacitor body part of the second plate of the capacitor; and
orthographic projections of the second capacitor body part and the second capacitor connection part on the substrate is overlapped at least partially with an orthographic projection of the first capacitor body part of the first plate of the capacitor on the substrate, and is not overlapped with an orthographic projection of the first capacitor connection part of the first plate of the capacitor on the substrate.

19. The display substrate according to claim 18, wherein an orthographic projection of the active layer of the sixth transistor on the substrate and an orthographic projection of the active layer of the fifth transistor on the substrate are located at two opposite sides of an orthographic projection of the signal output line on the substrate respectively, and a straight line extending along the first direction passes through the active layer of the fifth transistor and the active layer of the sixth transistor;
a straight line extending along the first direction passes through the active layer of the fourth transistor and the third active connection part of the active layer of the third transistor; and
a straight line extending along the first direction passes through the active layer of the ninth transistor and the active layer of the eighth transistor, and a straight line extending along the first direction passes through the active layer of the tenth transistor and the active layer of the seventh transistor.

20-23. (canceled)

24. A display device, comprising the display substrate according to claim 12.

25. (canceled)
